(19) United States
(12) Patent Application Publication
(10) Pub. No.: US 2026/0092375 A1
(43) Pub. Date: Apr. 2, 2026

(54) SUPRAMOLECULAR ORGANOMETALLIC CURABLE FLUIDS TO COAT SUBSTRATES WITH METAL CARBIDES

(71) Applicant: Wolfspeed, Inc., Durham, NC (US)

(72) Inventors: Alexander SHVEYD, Chapel Hill, NC (US); Simon BUBEL, Carrboro, NC (US)

(21) Appl. No.: 18/963,196

(22) Filed: Nov. 27, 2024

Related U.S. Application Data
(60) Provisional application No. 63/700,685, filed on Sep. 28, 2024.

(51) Int. Cl. C23C 18/12; C30B 23/00

(52) U.S. Cl. CPC C23C 18/1204; C23C 18/1245; C23C 18/1279; C30B 23/005

(57) ABSTRACT

An organometallic compound is provided which includes a central metal atom; and organic ligands capable of forming polydentate bonds to the central metal atom. Related methods and articles having a metal carbide coating are also provided.

### TECHNICAL FIELD

The present disclosure relates generally to organometallic compounds which include a central metal atom and organic ligands capable of forming polydentate bonds to the central metal atom, and related methods and articles having a metal carbide coating.

### BACKGROUND

Semiconductor devices, including power semiconductor devices based on wide bandgap materials, may be formed on a semiconductor wafer as part of a semiconductor fabrication process. Single crystal silicon carbide (SiC) has proven to be a very useful wafer material in the manufacture of such semiconductor devices. Due to its physical strength and excellent resistance to many chemicals, silicon carbide may be used to fabricate very robust substrates adapted for use in the semiconductor industry. Silicon carbide has excellent electrical properties, including radiation hardness, high breakdown field, a relatively wide band gap, high saturated electron drift velocity, high-temperature operation, and absorption and emission of high-energy photons in the blue, violet, and ultraviolet regions of the optical spectrum.

The graphite materials used in bulk crystal reactors and epitaxial growth reactors are subjected to a corrosive and high temperature environment. Reactive gaseous species used in such processes, like Si, Si₂C and SiC₂, chemically etch the graphite surfaces. The components used in the crucible are often limited to a single use, and costly larger parts inside the grower chamber break down with successive crystal growths. The deterioration of graphite has other detrimental consequences by introducing defects which impact the crystal quality. As the graphite of the crucible breaks down, microparticles are generated. When these fragments are incorporated into the growing crystal, they become a graphite inclusion defect which can lead to more pervasive crystal defects like dislocations and micropipes. Chemical etching can also have other unintended consequences because it alters the precise geometries of the graphite parts, impacting the sensitive thermal conditions needed to grow high-quality crystals.

To protect the graphite from degradation during SiC crystal growth, parts may be coated with tantalum carbide (TaC), a refractory ceramic that has exceptional hardness, high melting point, low chemical reactivity, and robust thermal stability at high temperatures.

### SUMMARY

There currently exist certain challenges in coating graphite and other materials with metal carbide. For example, one current approach used to coat graphite with TaC uses chemical vapor deposition (CVD) through the chlorination, oxidation, and then carbothermic reduction of tantalum metal. To grow a TaC coating on a graphite part, toxic chlorine gas is delivered to the reactor which generates the side product tantalum pentachloride that must be disposed of post-processing. There are significant manufacturing costs associated with the infrastructure needed to handle these challenging materials. Tuning the layer thickness and scaling the process is also not trivial. The carbon source in the TaC coating, which originates from the graphite substrate, is diffusion-limited. Carbon atoms migrate through a growing layer of TaC to react with newly deposited Ta ions at the surface to keep growing the coating. This reaction mechanism produces an upper bound of about 35 μm on the final thickness that can be achieved and limits the growth rate of the coating to about 35 μm per 50 hours of processing. Yet another shortcoming of some approaches using a CVD process is that the impurity grade of TaC coated products may be influenced by the impurities of any part processed in the CVD reactor, effectively limiting the process to purified graphite only. There is also an upper bound on the size and quantity of parts that can be coated simultaneously with some CVD reactors. Another significant drawback of some approaches is a limitation to coating hard graphite only. Grower components not made from hard graphite therefore cannot be TaC coated using some approaches.

Certain aspects of the disclosure and their embodiments may provide solutions to these or other challenges.

In contrast to existing approaches, certain aspects of the disclosure and their embodiments may allow graphite and other materials to be coated with metal carbides, including TaC: (1) using less toxic starting reagents; (2) using comparatively simple processing steps; (3) producing smaller quantities of waste, which may also be less toxic; (4) generating TaC films at lower temperatures; (5) having a tunable thickness range; (6) coating various graphite substrates and geometries.

Certain aspects of the disclosure and their embodiments describe a family of compounds that will be referred to as supramolecular organometallic curable fluids (SOCF) because of the extensive non-covalent interactions (e.g., chelate effect, charge transfer) that effectively stabilize the metal center in the complex against hydrolysis and form a highly coupled supramolecular network. These stabilizing supramolecular interactions in SOCFs allow the liquid to polymerize into air-stable crack-free coatings that pyrolyze into high-quality ceramic films.

Certain aspects of the disclosure and their embodiments describe a method of creating an article for use in a crystal growth system, including applying an organometallic compound to at least one surface of an article, wherein the at least one surface of the article contains carbon or an oxide; curing the organometallic compound on the at least one surface of the article; and heating the organometallic compound on the at least one surface of the article such that the metal carbide coating is formed on the at least one surface of the article; wherein the organometallic compound consists of: a central metal atom; and ligands capable of forming polydentate bonds to the central metal atom.

Certain aspects of the disclosure and their embodiments describe a crystal growth system for growing crystalline material, including at least one graphite component, wherein this at least one graphite component has had an organometallic compound is applied to at least one surface, the applied organometallic compound having been cured and heated to form a metal carbide coating on the at least one surface of the article; wherein the organometallic compound consists of: a central metal atom; and ligands capable of forming polydentate bonds to the central metal atom.

Certain aspects of the disclosure and their embodiments describe an organometallic compound which includes a central metal atom; and organic ligands capable of forming polydentate bonds to the central metal atom.

Certain aspects of the disclosure and their embodiments describe a method of synthesizing an organometallic compound, including mixing a liquid metal alkoxide reagent having a central metal atom and alkoxide ligands where a conjugate base of the ligands is a volatile liquid alcohol, with a liquid ligand-generating reagent; and placing the mixture under reduced pressure sufficient to evaporate the volatile liquid alcohol from the mixture.

Certain aspects of the disclosure and their embodiments describe an article having a metal carbide coating, including an organometallic compound applied to at least one surface of an article that contains carbon or an oxide, the applied organometallic compound having been cured and pyrolyzed to form a metal carbide coating on the at least one surface of the article wherein the organometallic compound consists of: a central metal atom; and ligands capable of forming polydentate bonds to the central metal atom.

Certain aspects of the disclosure and their embodiments describe an epitaxial product including an epitaxial wafer or boule formed of a single crystal layer containing a group IV element, said epitaxial wafer or boule having metal carbide impurities.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

The accompanying drawings, which are included to provide a further understanding of the disclosure and are incorporated in and constitute a part of this application, illustrate certain non-limiting embodiments of inventive concepts. In the drawings:

FIG. 1 depicts a crystal growth system having a treated graphite structure according to example embodiments of the present disclosure;

FIG. 2 depicts a crystal growth system having a treated graphite structure according to example embodiments of the present disclosure;

FIG. 3 depicts a crystal growth having a treated graphite structure according to example embodiments of the present disclosure;

FIG. 4A is an exemplary line formula of tantalum ethylglycolate.

FIG. 4B is an exemplary line formula of tantalum diethylglycolate

FIG. 4C is an exemplary line formula of tantalum glycerolate.

FIGS. 5A and 5B are line formulas for exemplary diethylglycolate SOCFs showing exemplary hydrogen bonding between two SOCF molecules.

FIGS. 6A, 6B, 6C, and 6D are line formulas for exemplary SOCFs showing exemplary stabilizing effects from polydentate ligands.

FIG. 7 is a reaction mechanism for an exemplary glycolate SOCF via ligand substitution.

FIG. 8 is a flowchart illustrating a method for creating an article for use in a crystal growth system of applying a metal carbide coating to at least one surface of an article.

FIG. 9 is a flowchart illustrating a method of synthesizing an organometallic compound.

FIG. 10A depicts a perspective view of a source retention mechanism according to example embodiments of the present disclosure.

FIG. 10B depicts a perspective view of a source retention mechanism according to example embodiments of the present disclosure.

FIG. 11 depicts a crystal growth system having a treated graphite structure according to example embodiments of the present disclosure.

FIGS. 12A-C depict a crystal growth system that may utilize components according to example embodiments of the present disclosure.

FIG. 13 depicts a crystal growth system that may utilize components according to example embodiments of the present disclosure.

FIG. 14 depicts a crystal growth system that may utilize components according to example embodiments of the present disclosure.

FIG. 15 depicts a crystal growth system that may utilize components according to example embodiments of the present disclosure.

FIG. 16 depicts a crystal growth system that may utilize components according to example embodiments of the present disclosure.

FIG. 17 depicts a crystal growth system that may utilize components according to example embodiments of the present disclosure.

FIG. 18 depicts a crystal growth system that may utilize components according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations may be made to the embodiments without departing from the scope or spirit of the present disclosure. For instance, features illustrated or described as part of one embodiment may be used with another embodiment to yield a still further embodiment. Thus, it is intended that aspects of the present disclosure cover such modifications and variations.

Aspects of the present disclosure are directed to graphite structures used in crystal growth systems, such as silicon carbide crystal growth systems.

Graphite structures may be used in crystal growth systems, including for example CVD, physical vapor transport (PVT), and hybrid systems. For instance, in some examples, graphite structures may accommodate a flow of a fluid (e.g., vapor or gas) during sublimation of a source material. For instance, the graphite structure may act as a source filter for sublimation from the source to the seed material during a crystal growth process.

Although TaC may extend the lifetime of graphite parts, it has limitations. For example, depositing TaC on graphite using a CVD deposition process may adequately coat the smaller hard graphite components in the crucible, while not adequately coating other graphite components in the crucible. In the grower-crucible system, there can be at least four graphite parts or components susceptible to degradation. These parts can vary greatly in size, shape, and cost. In some coating approaches, the expensive larger components which are not made from hard graphite, for example, cannot by protected from degradation. Another limitation of some coating approaches is a narrow thickness range of a coating, which is a feature constrained by the CVD chemistry being used. Other drawbacks of some coating approaches include high fabrication costs, large and specialized equipment for high temperature processing, highly toxic processing reagents, and corrosive waste byproducts. All these examples demonstrate the limited flexibility and scalability of some approaches including, for example, current approaches using a TaC deposition system.

Inventive concepts will now be described more fully hereinafter with reference to the accompanying drawings, in which examples of embodiments of inventive concepts are shown. Inventive concepts may, however, be embodied in many different forms and should not be construed as limited to the embodiments set forth herein. Rather, these embodiments are provided so that this disclosure will be thorough and complete, and will fully convey the scope of present inventive concepts to those skilled in the art. It should also be noted that these embodiments are not mutually exclusive. Components from one embodiment may be tacitly assumed to be present/used in another embodiment.

Articles for use in a crystal growth system in accordance with the present disclosure may be created by applying an organometallic compound to at least one surface of an article, wherein the at least one surface of the article contains carbon or an oxide, curing the organometallic compound on the at least one surface of the article; and heating the organometallic compound on the at least one surface of the article such that the metal carbide coating is formed on the at least one surface of the article, wherein the organometallic compound includes a central metal atom; and ligands capable of forming polydentate bonds to the central metal atom.

In some embodiments, the article for use in a crystal growth system is one of a seed holder, crucible, lid, spacer ring, rod, liner, washer, shaft, porous barrier, or filter. In some embodiments, the crystal growth system is a silicon carbide crystal growth sublimation system.

In some embodiments, the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom is tantalum.

In some embodiments, the ligands capable of forming polydentate bonds to the central metal atom are polar. In some embodiments, the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some embodiments, the article is made from a material is selected from the group consisting of graphite, hard carbon, carbon fiber, felt carbon, vitreous carbon, pyrolytic carbon, silicon carbide, tungsten carbide, quartz, glass, ferric oxides, magnesium oxides, aluminum oxides, titanium oxides, cerium oxide, niobium oxide, and zinc oxide. In some embodiments, the at least one surface of the article is porous. In some embodiments, the at least one surface of the article is nonporous.

In some embodiments, the organometallic compound on the at least one surface of the article is cured at about 25° C. and at ambient pressure. In some embodiments, the organometallic compound on the at least one surface of the article is heated at 2000° C. or less, or at 1700° C. or less, or at 1500° C. or less. In some embodiments, the organometallic compound on the at least one surface of the article is heated for 24 hours or less. In some embodiments, the metal carbide coating is formed on the at least one surface of the article has a thickness greater than 35 μm.

In some embodiments, the central metal atom and ligands of the organometallic compound are selected such that the organometallic compound is a liquid at 25° C. and 1 atm. In some embodiments, the alkyl group of the alkyl amines, alkyl acetates, alkyl alcohols, alkyl glycols, alkyl diols, alkyl nitrites, alkyl halides, alkyl aromatics, or alkylated charge transfer donor-acceptor pairs is an ethyl, propyl, butyl group, or a mixture thereof. In some embodiments, all of the ligands are the same. In some embodiments, the ligands are selected from the group of glycolate, diethylene glycolate, glycerolate, or a mixture thereof. In some embodiments, the organometallic compound is tantalum ethylglycolate, or is tantalum diethylglycolate, or is tantalum glycerolate.

In some embodiments, the organometallic compound is applied to the at least one surface of the article via at least one of a spray application, dip application, electrostatic application. In some embodiments, the organometallic compound is applied to the at least one surface of the article in a solvent.

Crystal growth systems for growing crystalline material in accordance with the present disclosure may include at least one graphite component, wherein this at least one graphite component has had an organometallic compound is applied to at least one surface, the applied organometallic compound having been cured and heated to form a metal carbide coating on the at least one surface of the article wherein the organometallic compound consists of a central metal atom and ligands capable of forming polydentate bonds to the central metal atom.

In some embodiments, the at least one graphite component is a seed holder, crucible, lid, spacer ring, rod, liner, washer, shaft, porous barrier, or filter. In some embodiments, the crystal growth system is a silicon carbide crystal growth sublimation system.

In some embodiments, the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom is tantalum.

In some embodiments, the ligands capable of forming polydentate bonds to the central metal atom are polar. In some embodiments, the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some embodiments, the at least one surface of the article is porous. In some embodiments, the at least one surface of the article is nonporous.

In some embodiments, the organometallic compound on the at least one surface of the article is cured at about 25° C. and at ambient pressure. In some embodiments, the organometallic compound on the at least one surface of the article is heated at 2000° C. or less, or 1700° C. or less, or 1500° C. or less. In some embodiments, the organometallic compound on the at least one surface of the article is heated for 24 hours or less. In some embodiments, the metal carbide coating is formed on the at least one surface of the article has a thickness greater than 35 μm.

In some embodiments, the central metal atom and ligands of the organometallic compound are selected such that the organometallic compound is a liquid at 25° C. and 1 atm. In some embodiments, the alkyl group of the alkyl amines, alkyl acetates, alkyl glycols, alkyl alcohols, alkyl diols, alkyl nitrites, alkyl halides, alkyl aromatics, or alkylated charge transfer donor-acceptor pairs is an ethyl, propyl, butyl group, or a mixture thereof. In some embodiments, all of the ligands are the same. In some embodiments, the ligands are selected from the group of glycolate, diethylene glycolate, glycerolate, or a mixture thereof. In some embodiments, the organometallic compound is tantalum ethylglycolate, or is tantalum diethylglycolate, or is tantalum glycerolate.

In some embodiments, the organometallic compound is applied to the at least one surface of the article via at least one of a spray application, dip application, electrostatic application. In some embodiments, the organometallic compound is applied to the at least one surface of the article in a solvent.

Organometallic compounds in accordance with the present disclosure may include a central metal atom and organic ligands capable of forming polydentate bonds to the central metal atom.

In some embodiments, the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom is tantalum.

In some embodiments, the ligands capable of forming polydentate bonds to the central metal atom are polar. In some embodiments, the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof. In some embodiments, the alkyl groups of the alkyl amines, alkyl acetates, alkyl alcohols, alkyl glycols, alkyl diols, alkyl nitrites, alkyl halides, alkyl aromatics, or alkylated charge transfer donor-acceptor pairs is an ethyl, propyl, butyl group, or a mixture thereof.

In some embodiments, the central metal atom and ligands are selected such that the organometallic compound is a liquid at 25° C. and 1 atm. In some embodiments, the ligands are selected from the group of glycolate, diethylene glycolate, glycerolate, or a mixture thereof. In some embodiments, all of the ligands are the same. In some embodiments, the organometallic compound is tantalum ethylglycolate, or is tantalum diethylglycolate, or is tantalum glycerolate.

The SOCFs in accordance with the present disclosure may be synthesized by mixing a liquid metal alkoxide reagent having a central metal atom and alkoxide ligands where a conjugate base of the ligands is a volatile liquid alcohol, with a liquid ligand-generating reagent; and placing the mixture under reduced pressure sufficient to evaporate the volatile liquid alcohol from the mixture. In some embodiments, the liquid metal alkoxide reagent may be mixed with the liquid ligand-generating reagent, such that the alkoxide ligands of the metal alkoxide reagent are substituted with a conjugate ligand from the ligand-generating reagent to produce the organometallic compound and the displace ligands become volatile liquid alcohol.

In some embodiments, the central metal atom of the metal alkoxide reagent may be selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom of the metal alkoxide reagent may be selected to be tantalum.

In some embodiments, the alkoxide ligands of the metal alkoxide reagent may be selected from a group consisting of ethoxides, propoxides, butoxides, or a mixture thereof. In some embodiments, all of the ligands of the metal alkoxide reagent may all be the same. For example, the metal alkoxide reagent may be tantalum ethoxide.

In some embodiments, the ligand-generating reagent may be selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some embodiments, the alkyl groups of the alkyl amines, alkyl acetates, alkyl alcohols, alkyl glycols, alkyl diols, alkyl nitrites, alkyl halides, alkyl aromatics, or alkylated charge transfer donor-acceptor pairs may be an ethyl, propyl, butyl group, or a mixture thereof. In some embodiments, the metal center and alkyl groups may be selected such that the organometallic compound is a liquid at 25° C. and 1 atm. In some embodiments, the ligand-generating reagent may be selected from the group of ethylene glycol, diethylene glycol, glycerol, or a mixture thereof.

In some embodiments, the synthesis of the organometallic compound is performed at about 25° C. and 1 atm. And in some embodiments, the synthesis of the organometallic compound is performed until substantially all of the alkoxide ligands of the metal alkoxide reagent are substituted with the conjugate ligand from the ligand-generating reagent.

Articles having a metal carbide coating in accordance with the present disclosure may include an organometallic compound applied to at least one surface of an article that contains carbon or an oxide, the applied organometallic compound having been cured and pyrolyzed to form a metal carbide coating on the at least one surface of the article wherein the organometallic compound includes a central metal atom and ligands capable of forming polydentate bonds to the central metal atom.

In some embodiments, the central metal atom of the metal alkoxide reagent may be selected from the group consisting of chromium, hafnium, iridium, molybdenum, niobium, osmium, rhenium, rhodium, ruthenium, tantalum, titanium, tungsten, vanadium, zirconium, or a mixture thereof. In some embodiments, the central metal atom of the metal alkoxide reagent may be selected to be tantalum.

In some embodiments, the alkoxide ligands of the metal alkoxide reagent may be selected from a group consisting of ethoxides, propoxides, butoxides, or a mixture thereof. In some embodiments, all of the ligands of the metal alkoxide reagent may all be the same. For example, the metal alkoxide reagent may be tantalum ethoxide.

In some embodiments, the ligands capable of forming polydentate bonds to the central metal atom may be polar. In some embodiments, the ligands capable of forming polydentate bonds to the central metal atom may be selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

In some embodiments, the article is made from a material selected from the group consisting of graphite, hard carbon, carbon fiber, felt carbon, vitreous carbon, pyrolytic carbon, silicon carbide, tungsten carbide, quartz, glass, ferric oxides, magnesium oxides, aluminum oxides, titanium oxides, cerium oxide, niobium oxide, and zinc oxide. In some embodiments, the at least one surface of the article is porous. In some embodiments, the at lease one surface of the article is nonporous

In some embodiments, the alkyl groups of the alkyl amines, alkyl acetates, alkyl alcohols, alkyl glycols, alkyl diols, alkyl nitrites, alkyl halides, alkyl aromatics, alkylated charge transfer donor-acceptor pairs, may be an ethyl, propyl, butyl group, or a mixture thereof. In some embodiments, the metal center and alkyl groups may be selected such that the organometallic compound is a liquid at 25°C. and 1 atm. In some embodiments, the ligands may be selected from the group of ethylene glycol, diethylene glycol, glycerol, or a mixture thereof. In some embodiments, the ligands are all the same. In some embodiments, the organometallic compound is tantalum ethylglycolate, tantalum diethylglycolate, tantalum glycerolate.

In some embodiments, the organometallic compound on the at least one surface of the article is cured at about 25° C. and at ambient pressure. In some embodiments, the organometallic compound on the at least one surface of the article is pyrolized at 2000° C. or less, or at 1700° C. or less, or at 1500° C. or less. In some embodiments, the organometallic compound on the at least one surface of the article is pyrolyzed for 24 hours or less. In some embodiments, the metal carbide coating is formed on the at least one surface of the article has a thickness greater than 35 μm.

In some embodiments, compounds, materials, and methods disclosed herein may be used to create a coating, surface treatment, or subsurface treatment for any part of a crystal growth system, including but not limited to a source or a baffle. Such parts may include an engineered structure having a construction or configuration that is or includes one or more of a porous structure, woven wire, perforated plate, foam, screen printed material, refractory metal, 3D printed structure, coated wire, carbon fiber mesh, carbon wires, refractory metal wires, woven mesh, cast component(s), grid, sintered powder, composite laminate, electroformed structure, braided wire, honeycomb structure, felt structure, nanostructured film, carbon nanotubes, tightly or loosely interconnected network of structures or other suitable construction or configuration. One or more combinations of any of these constructions or configurations may be used without deviating from the scope of the present disclosure. For example, in some embodiments, a first baffle structure (e.g., a first baffle plate) may include a first configuration (e.g., porous material) and a second baffle structure (e.g., a second baffle plate) may include a second configuration (e.g., honeycomb structure).

In the drawings and specification, there have been disclosed typical embodiments and, although specific terms are employed, they are used in a generic and descriptive sense only and not for purposes of limitation of the scope set forth in the following claims.

One example of a crystal growth system is chemical vapor deposition (CVD). CVD is a process used to grow high-quality crystals of materials, especially semiconductors, metals, and other compounds, by transporting chemical species in vapor form from a source to a growth site. In CVD, a solid material (source) is heated in the presence of a transport agent, usually a halogen gas like iodine, chlorine, or bromine. The source material reacts with the transport agent to form a volatile compound, which is then transported to a cooler region of the chamber. Upon reaching the cooler region, the vaporized material decomposes or reacts to deposit the pure solid, resulting in crystal growth.

Another example of a crystal growth system is physical vapor transport (PVT). PVT is a process used to grow single crystals from the vapor phase without the use of a liquid or solution medium. This process involves sublimating a solid material, transporting the vapor to a cooler region of the chamber, and allowing the vapor to condense and crystallize on a substrate or seed crystal. Crystal growth systems may also be a hybrid of CVD and PVT processes.

Crystal growth systems may employ ultra-high temperatures. For example, systems for bulk crystal growth may reach temperatures in the range of 1700° C. to 2600° C. or higher. Also for example, systems for epitaxial growth may reach temperatures in the range of 900° C. to 1700° C.

One or more baffle structures may be used in crystal growth systems and deposition systems (e.g., epitaxial reactors), such as silicon carbide crystal growth sublimation systems to accommodate the transport (e.g., kinetic factors) of source material vapor while enhancing control over a thermal gradient or chemical environment. For instance, in some examples, a baffle may accommodate a transport of vapor (e.g., source material vapor) while providing a physical separation of chemical and/or thermal environments between a sublimating source material and a seed material experiencing deposition at a growth front. Such baffle structures may be created from or may have a coating created thereon according to certain embodiments of the present disclosure.

In some embodiments, the crystal growth system may include a baffle within the crystal growth chamber that may be spaced apart from the silicon carbide vapor source material.

In some embodiments, the baffle includes a porous material, such as porous graphite. In some examples, at least a portion of the baffle has a porosity of greater than about 50% by volume, such as greater than about 70% by volume, such as greater than 80% by volume. Porosity by volume expressed as a percentage refers to the percentage of the volume of voids in the baffle relative to the total volume of the material.

In some embodiments, the baffle includes one or more apertures defined through a thickness of the baffle. As used herein, an “aperture” is a defined opening, space, perforation, hole, or void in a structure that extends from one exterior surface of a structure to another exterior surface of the structure. In some embodiments, each of the one or more apertures provides a path through the baffle for transport of vapor from the silicon carbide source material to the seed crystal without having significant crystal growth formation in the aperture.

In some embodiments, the baffle has a long dimension that is generally non-perpendicular to the growth surface of the seed crystal. In some embodiments, the baffle has a thickness in a direction of vapor transport through the baffle. As used herein, the “width” or “width dimension” refers to a dimension of a baffle, an aperture, or other structure that runs in a plane that is perpendicular to the transport direction of vapor to the crystal growth system. The “long dimension” of a baffle, an aperture, or other structure refers to the longest dimension (e.g., greatest in magnitude) of the structure.

In some examples, the one or more apertures include a plurality of holes defined through the baffle. In some examples, the one or more apertures include an annular aperture defined through a thickness of the baffle. In some examples, a vapor transport direction through the one or more apertures is in a non-perpendicular direction relative to the growth surface of the seed crystal.

In some examples, the one or more apertures are arranged in the baffle to provide for non-uniform vapor transport from the source material to the seed crystal. As used herein, a baffle provides non-uniform vapor transport when vapor is transported through a first portion of the baffle at a first rate and is transported through a second portion of the baffle at a second rate. The first rate is different from the second rate. For instance, a baffle may include a first portion with one or more apertures that transports vapor at a first rate. The baffle may include a second portion without apertures that transports vapor at a second rate.

In some examples, the one or more apertures include a first aperture and a second aperture, wherein a width of the first aperture is different from a width of the second aperture. In some examples, the one or more apertures include a first plurality of apertures and a second plurality of apertures, wherein a density of the first plurality of apertures in the baffle is different from a density of the second plurality of apertures in the baffle. In some examples, the first plurality of baffles are in a central portion of the baffle and the second plurality of baffles are in a peripheral portion of the baffle. In some examples, the baffle includes a plurality of dividers arranged in a non-perpendicular direction relative to the growth surface of the seed crystal. In some examples, the one or more apertures are arranged to direct vapor in a direction that is more towards a center of the seed crystal relative to a peripheral portion of the seed crystal. In some examples, the one or more apertures are arranged to direct vapor in a direction that is more towards a peripheral portion of the seed crystal relative to a central portion of the seed crystal.

In some examples, at least one surface of the baffle may be flat, whereas in other examples, at least one surface of the baffle may be concave, convex, angled, or other topographies. In some examples, the surface of the baffle closest to the seed crystal may have a particular topography and the surface of the baffle furthest from the seed crystal may have a different topography.

In some examples, the baffle includes a plurality of baffle structures (e.g., baffle plates). In some examples, the baffle includes a first baffle plate having the one or more apertures and a second baffle plate with no apertures. In some examples, the baffle includes a first baffle plate includes a first aperture and a second baffle plate including a second aperture. In some examples, the first aperture is aligned with the second aperture. In some examples, the first aperture is not aligned with the second aperture. In some examples, the first aperture has a different width relative to the second aperture. In some examples, the baffle includes a first baffle plate including a first material and a second baffle plate including a second material. In some examples, the first baffle plate includes graphite and the second baffle plate includes a source material (e.g., carbon source material, carbon source material, etc.). In some examples, the baffle includes a third baffle plate, wherein the third baffle plate includes the first material. In some examples, the second baffle plate is arranged between the first baffle plate and the third baffle plate. In some examples, the first material includes graphite and the second material includes a source material (e.g., silicon carbide source material and/or carbon source material (e.g., graphite).

In some examples having a plurality of baffle structures, the baffle structures may be in contact with one another. In some examples, the plurality of baffle structures may not be in contact with one another. In some examples, the plurality of baffle structures may include other structures between them.

In some examples, the baffle includes graphite. In some examples, the baffle includes a coating on the graphite. In some examples, the coating is only on a portion of the baffle. In some examples, the baffle includes multiple coatings, including different regions of the baffle having distinct coatings. In some examples, the coating is a pyrolytic coating. In some examples, the coating includes tantalum carbide. In some examples, the graphite is porous graphite.

In some examples, the baffle is spaced apart from the seed holder and is not coupled to the seed holder. In some examples, the baffle is coupled to a side wall of the crucible.

In addition, the baffle, or a portion thereof, may potentially act as a second source (e.g., a carbon source). For instance, if a reactive material is used as a baffle, the baffle may be etched such that the baffle contributes positively to species interacting with the seed crystal during a growth process. The baffle, or a portion thereof, can be made of a reactive material that captures parasitic silicon carbide, or silicon carbide that crystallizes in an undesirable location, and act as a dynamic source if the captured silicon carbide is sublimated, if desired. Further, the baffle may act as an additional gas injection site for process gases.

In addition, if a large surface area of material that is non-reactive or inert with respect to carbon and silicon species is provided, the inert material may provide a catalytic surface that facilitates gas-gas reactions (e.g., to change ratios of silicon, carbon, and/or species containing silicon and/or carbon in the vapor). That is, gas stoichiometry in the vicinity of the baffle may be brought towards equilibrium. This may facilitate enhanced growth rates and less material waste. In some embodiments, at least a portion of the baffle may have a chemically active surface or coating that may be used to reduce contaminates, impurities, and inclusions in vapor transported through the baffle.

Examples of crystal growth systems, including crystal growth systems incorporating exemplary baffle structures are disclosed in U.S. patent application Ser. No. 18/962,454, filed on Nov. 27, 2024, which is incorporated herein by reference.

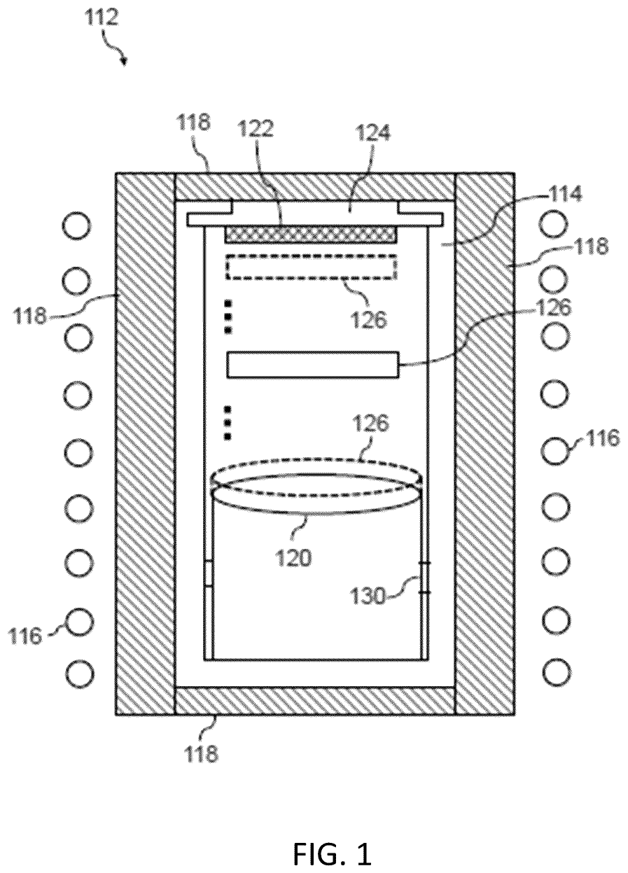

FIG. 1 is a cross-sectional schematic diagram of a crystal growth system 112 adapted for use in a crystal growth process of the type contemplated by certain embodiments of the disclosure. The crystal growth system 112 includes a reaction crucible 114 (also referred to as a susceptor or growth cell) and a plurality of induction coils 116 adapted to heat the reaction crucible 114 when electrical current is applied. Alternatively, a resistive heating approach may be applied to the heating of the reaction crucible 114. Using any competent heating mechanism and approach, the temperature within the crystal growth system 112 may be controllable. The reaction crucible 114 may be, at least in part, a graphite structure.

The crystal growth system 112 may also include one or more gas inlet and gas outlet ports and associated equipment allowing the controlled introduction and evacuation of gas from an environment surrounding the reaction crucible 114. The introduction and evacuation of various gasses to or from the environment surrounding the reaction crucible 114 may be accomplished using a variety of inlets/outlets, pipes, valves, pumps, gas sources, and controllers. It will be further understood by those skilled in the art, using the disclosures provided herein, that the crystal growth system 112 may further incorporate in certain embodiments a water-cooled quartz vessel.

The reaction crucible 114 may be surrounded by an insulation material 118. The composition, size, and placement of the insulation material 118 will vary with an individual crystal growth system, such as the crystal growth system 112 of FIG. 1, to define and/or maintain desired thermal gradients (both axially and radially) in relation to the reaction crucible 114. For purposes of clarity, the term, “thermal gradient,” will be used herein to describe one or more thermal gradient(s) associated with the reaction crucible 114. Those skilled in the art, using the disclosures provided herein, recognize that “the thermal gradient” established in embodiments of the disclosure will contain (or may be further characterized as having) axial and radial gradients, or may be characterized by a plurality of isotherms.

Prior to establishment of the thermal gradient, the reaction crucible 114 is loaded with a source material 120 (e.g., silicon carbide vapor source material, such as a silicon carbide powder or solid silicon carbide source). As such, the reaction crucible 114 includes one or more portions, at least one of which is capable of providing the source material 120. The source material 120 may be held in a lower portion of the reaction crucible 114, as is common for one type of crystal growth system, such as the crystal growth system 112 of FIG. 1.

A seed material 122 may be placed above or in an upper portion of the reaction crucible 114. The seed material 122 may take the form of a silicon carbide seed wafer having a diameter, for instance, from about 50 mm to about 310 mm. A silicon carbide crystal boule will be grown from the seed material 122 during a crystal growth process.

In the embodiment illustrated in FIG. 1, a seed holder 124 is used to hold the seed material 122. The seed holder 124 is securely attached to the reaction crucible 114 in an appropriate fashion. For example, in the orientation illustrated in FIG. 1, the seed holder 124 is attached to an uppermost portion of the reaction crucible 114 to hold the seed material 122 in a desired position. In some embodiments, the seed holder 124 is fabricated from carbon (e.g., graphite). The attachment of the seed material 122 (e.g., a seed wafer) to the seed holder 124 within the crystal growth system 112 may be made, for instance, by a uniform thermal contact. Various techniques may be used to implement a uniform thermal contact. For example, the seed material 122 may be placed in direct physical contact with the seed holder 124, or an adhesive may be used to fix the seed material 122 to the seed holder 124, so as to provide uniform conductive and/or radiative heat transfer over substantially the entire area between the seed material 122 and the seed holder 124.

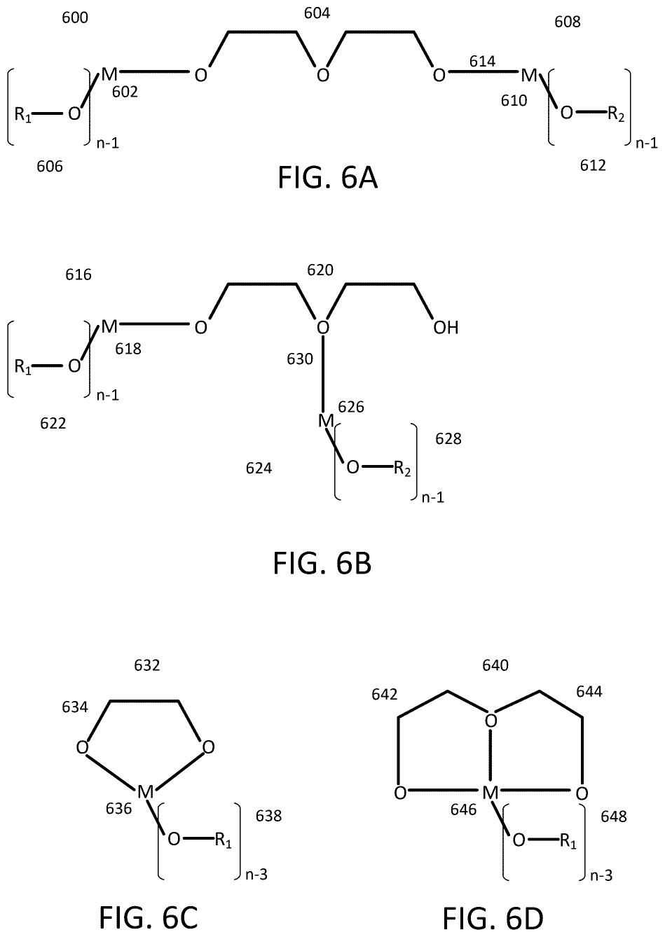

According to example aspects of the present disclosure, the crystal growth system 112 may include a baffle 126 that may be situated on the source material 120 or at any other location within the crystal growth system 112. The baffle 126 may provide a mechanism for transport of source vapor or other process gas during sublimation of the source material 120. The baffle 126 may filter or otherwise reduce impurities from the source material 120 that may inadvertently sublimate in a crystal growth process. The baffle may have any spatial orientation relative to the source material 120, the seed material 122, and/or the reaction crucible 114. The baffle 126 may include any of the baffles discussed in relation to FIGS. 6A-12.

Further, the crystal growth system 112 may optionally include the source material holder 130. The source material holder 130 may be, for example, one or more graphite components within the reaction crucible 114 that brace or support the shaped solid source material 120. In some embodiments, the source material holder 130 may be attached to the inner walls of the reaction crucible 114, as shown in FIG. 1.

FIG. 1 depicts a coordinate system having an x-axis as a horizontal axis, a y-axis that is in and out of the page, and a z-axis that is a vertical axis. A width dimension refers to a dimension along the x-axis or y-axis. A thickness dimension refers to a dimension along the z-axis. For the sake of clarity, any dimension along the x-axis or y-axis may be considered a width dimension regardless of whether it is the shortest or longest dimension in a plane defined by the x-axis and y-axis.

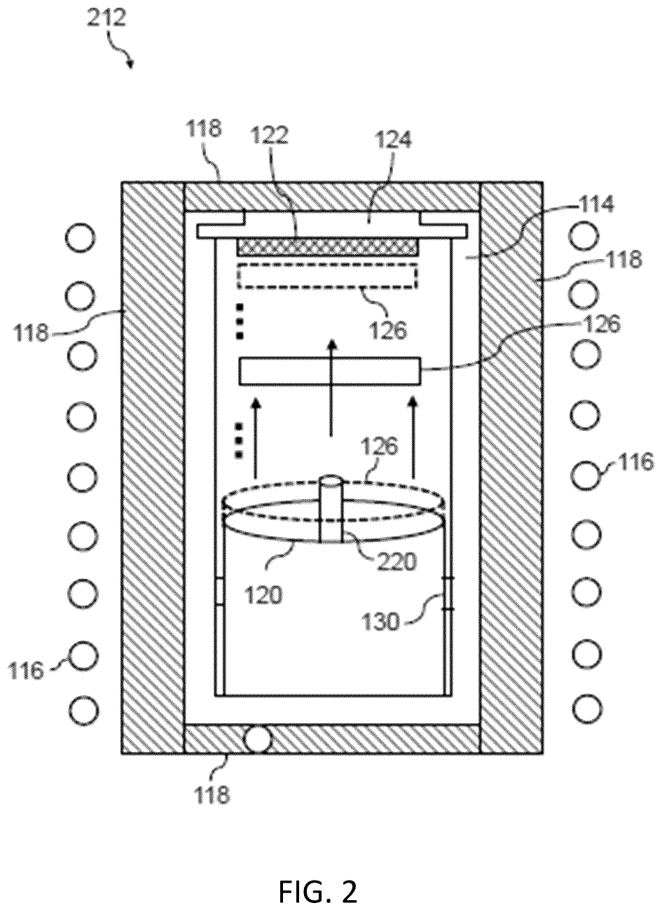

In one example embodiment, shown in FIG. 2, the crystal growth system 132 may be similar to that shown in FIG. 1, but may also include an inlet 134 for introducing a dopant (e.g., N₂) to the reaction crucible 114. The inlet 134, may be, for example, a tube, pipe, vent, or the like. In some embodiments, the source material 120 may surround the inlet 134. For example, in some embodiments, the source material 120 may include a channel through which the inlet 134 is provided. In other embodiments, the source material 120 may include a plurality of subcomponents (attached or detached) which surround the inlet 134. The inlet 134 may be connected to a dopant-containing gas source (not shown) and configured to introduce the dopant-containing gas to the reaction crucible 114. An example of a dopant-containing gas is nitrogen.

The crystal growth system 132 may include the baffle 126 that may be situated within the reaction crucible 114. The baffle 126 may provide a mechanism for the transport of source vapor during sublimation of the source material 120. The baffle 126 may have any spatial orientation relative to the source material 120, the seed material 122, and/or the reaction crucible 114. The baffle 126 may filter or otherwise reduce impurities from the source material 120 that may inadvertently sublimate in a crystal growth process. The baffle 126 may include any of the baffles discussed in relation to FIGS. 6A-12.

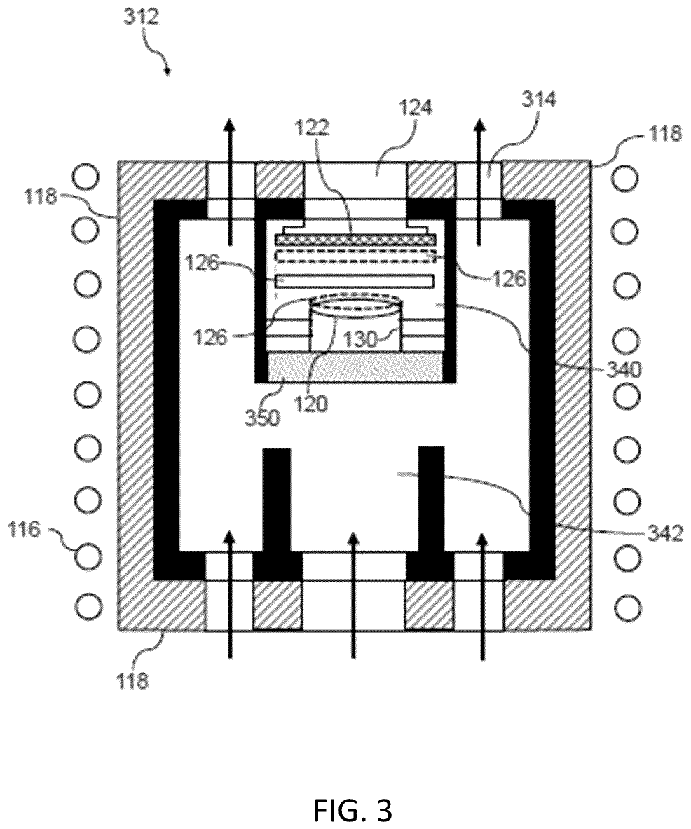

In another example embodiment, shown in FIG. 3, the crystal growth system 142 may be a continuous feed PVT (CF-PVT) system. In a CF-PVT system, such as the crystal growth system 142 of FIG. 3, the reaction crucible may include an upper chamber 144 and a lower chamber 146. The upper chamber 144 may include the source material 120 and the seed material 122. The upper chamber 144 may be separated from the lower chamber 146 by a foamed structure 150. The foamed structure 150 may be formed, for example, from a gas-permeable graphite foam. The source material 120 may be placed on the foamed structure 150 within the upper chamber 144. A gaseous silicon source (e.g., trimethylsilane diluted in argon) may be supplied to the lower chamber 146. As the gaseous silicon source is transported through the foamed structure 150, it may react with a carbon source within the foamed structure 150 (e.g., graphite) to form silicon carbide. A CF-PVT system, such as the crystal growth system 142 of FIG. 3, combines a PVT process for the growth of single crystals and high temperature chemical vapor deposition (HTCVD) processes for the in-situ formation and continuous feeding of a high purity polycrystalline source. A CF-PVT system, such as the crystal growth system 142 of FIG. 3, may be particularly useful for growing 3C silicon carbide.

The crystal growth system 142 may include a baffle 126 that may be situated within the upper chamber 144 of the reaction crucible. The baffle 126 may provide a mechanism for the transport of source vapor during sublimation of the source material 120. The baffle 126 may filter or otherwise reduce impurities from the source material 120 that may inadvertently sublimate in a crystal growth process. The baffle 126 may have any spatial orientation relative to the source material 120, the seed material 122, and/or the upper chamber 144 of the reaction crucible. The baffle 126 may include any of the baffles discussed in relation to FIGS. 6A-12.

In any of the embodiments shown in FIGS. 1-3, the crystal growth systems 112, 132, 142, and/or the reaction crucible 114 may be implemented in a number of different geometries, or any suitable configurations, and may hold the source material 120 accordingly. Thus, while embodiments of the present disclosure may be illustrated with certain designs of the reaction crucible 114, the scope of the present disclosure is not limited to such designs but will find application in different crystal growth system designs using many different types of reaction crucibles. In some examples, the crystal growth processes (e.g., the processes conducting in any of the embodiments shown in FIGS. 1-3) may be conducted at process temperatures in a range of 1700° C. to about 2600° C.

As shown in FIG. 1, the baffle 126 or baffle elements may be located on the source material, may be spaced apart from the source material 120 and/or the seed material 122, or may be proximate the seed material 122. In some embodiments, the system 112 may include any number of baffles or baffle elements 126 without deviating from the scope of the present disclosure. In some embodiments, the source material 120 may have a baffle 126 or baffle element incorporated therein.

Example silicon carbide source materials are disclosed in U.S. Provisional Application Ser. No. 63/689,294, filed on Aug. 30, 2024 and in U.S. Provisional Application Ser. No. 63/689,291, filed on Aug. 30, 2024, both of which are incorporated herein by reference.

The use of 3D printing to create parts and structures to be used in a crystal growth system or the source is disclosed in U.S. Provisional Application Ser. No. 63/689,298, filed on Aug. 30, 2024, which is incorporated herein by reference.

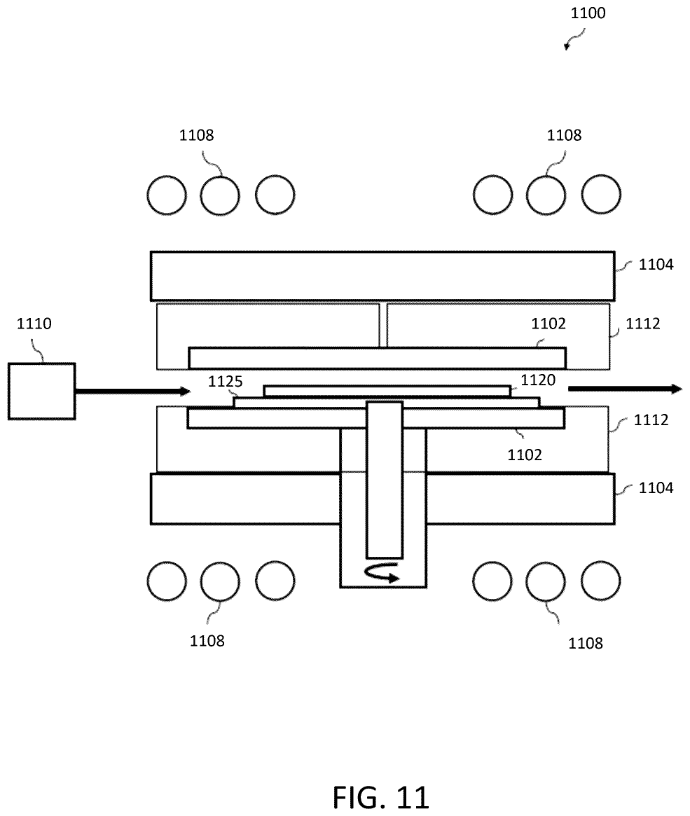

FIG. 11 depicts an example deposition system 1100 (e.g., epitaxial reactor) that may include structures according to example embodiments of the present disclosure. The deposition system 1100 may be a horizontal, hot wall, flow through, warm wall, and shower head CVD system as shown including a susceptor assembly 1102, a quartz tube 1104 defining a through passage 1106, an electromagnetic frequency (EMF) generator 1108 (for example, including a power supply and an RF coil surrounding the tube 1104) and a process gas supply system 1110. An insulative cover 1112 may be provided about the susceptor assembly 1102 in addition to or in place of the quartz tube 1104 The deposition system 1100 may be used to form a layer or film (e.g., epitaxial layer) on a workpiece 1120 (e.g., a silicon carbide semiconductor wafer). In some examples, the deposition process using the deposition system 1100 may occur at a process temperature in a range of about 900° C. to about 1700°C. While only a single workpiece 1120 is shown in FIG. 11, the system 1100 may be adapted to form films concurrently on multiple workpieces without deviating from the scope of the present disclosure.

The workpiece 1120 may be on a workpiece holder 1125. The workpiece holder 1125, in some examples, may be coupled to a rotation shaft to provide rotation of the workpiece 1120 during processing.

In some embodiments, the process gas supply system 1110 may supply a process gas into and through the susceptor assembly 1102 as discussed below. The EMF generator 1108 inductively heats the susceptor assembly 1102 to provide a hot zone in the susceptor assembly 1102 where deposition reactions take place. The process gas continues through and out of the susceptor assembly 1102 as an exhaust gas which may include remaining components of the process gas as well as reaction by-products, for example.

The susceptor assembly 1102 and/or the insulative cover 1112 may be, at least in part, a structure having a metal carbide coating. In some embodiments, the susceptor assembly 1102 and/or the insulative cover 1112 may be a structure according to example embodiments of the present disclosure.

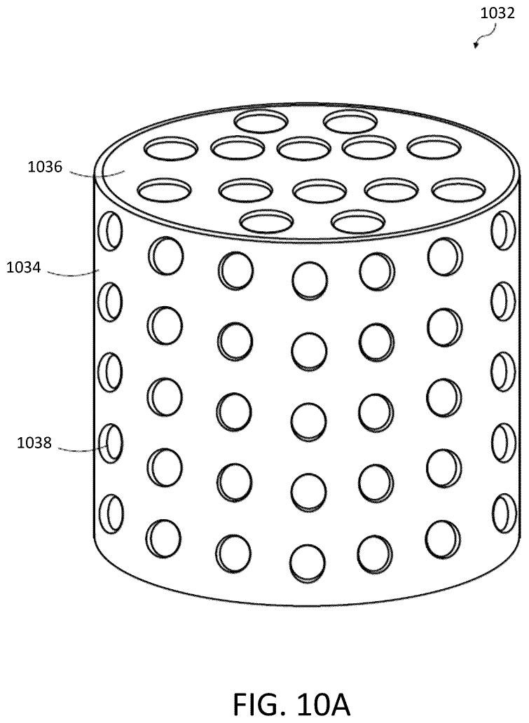

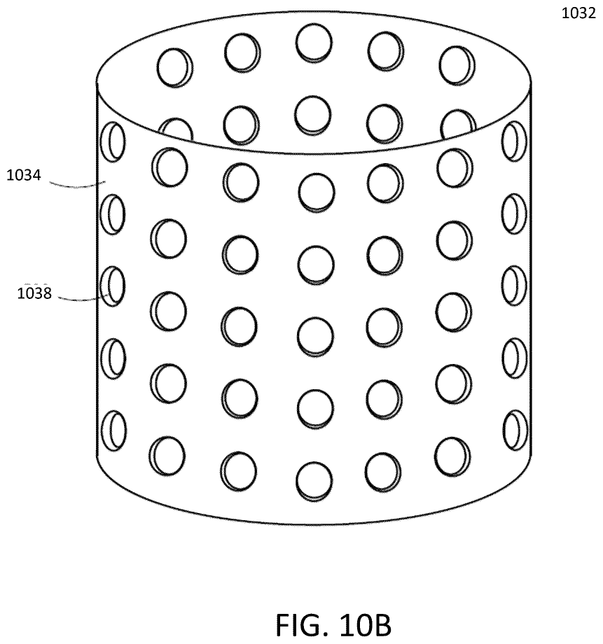

Crystal growth systems may also include source retention mechanisms. Example embodiments of source retention mechanisms are shown in FIGS. 10A and 10B. In FIG. 10A, the source retention mechanism 1032 contains cylindrical side walls 1034, a cap 1036, and channels 1038 formed in the side walls 1034 and cap 1036. As shown in FIG. 10A, the channels may all have the same or a similar diameter. In some embodiments, the diameters of the channels may be different and designed based on desired vapor flow paths and flowrates. For example, in some embodiments, the cap may have larger channels, or even one large central channel, relative to smaller or no peripheral channels.

The retention mechanism can be used to contain a source material, particularly when it is formed from multiple separate shaped solids (e.g., spheres). The channels 1038 allow sublimated vapor to escape into the main chamber of the reaction crucible where they can reach the seed material or growing crystal. The channels may be designed/located to control the vapor flow within the crucible. For example, they can direct the vapor to specific parts of the seed material or growing crystal. In some embodiments, the channels in the side walls 1034 may be omitted so that sublimated vapor can only exit through the channels in the cap 1036. In some embodiments, the cap 1036 may be omitted, as shown in FIG. 10B. In some embodiments, rather than, or in addition to, channels 1038, the source walls and/or cap of the retention mechanism that may be made from a highly porous material that the sublimated vapor can escape through.

In some embodiments, it may be desired to restrict vapor flow from either the sides or the top. As such, the sides or top of the retention mechanism may be formed from a material with no or relatively low porosity. The retention mechanism may be formed from graphite, silicon carbide, or any other suitable material. When the retention mechanism is formed from silicon carbide, it may act as an additional solid source structure. The retention mechanism may be sized to fit within the inner walls of the crucible. The retention mechanism may contact the sidewalls of the crucible or may be spaced apart from them, leaving paths for vapor flow radially outward from the retention mechanism.

Aspects of the present disclosure relate to a family of novel compounds referred to as supramolecular organometallic curable fluids (SOCF) because of the extensive non-covalent interactions that effectively stabilize the metal center in the complex against hydrolysis and form a highly coupled supramolecular network.

Based on the molecular features that destabilize metal alkoxides toward hydrolysis, the generalized molecular design of some SOCFs include: (1) having ligands that possess adequate conformational freedom to prevent the complex from solidifying at room temperature; (2) having ligands that are polydentate, capable of coordinating to a metal center through two or more atoms; (3) having ligands large enough to coordinate to more than one metal center as a bridging ligand; (4) having ligands capable of forming stabilizing intermolecular interactions with neighboring ligands, including hydrogen bonds, charge transfer, pi-pi stacking, among others; (5) excluding the coordinating atom, having ligands with low reactivity; and (6) having ligands derived from a precursor with low toxicity.

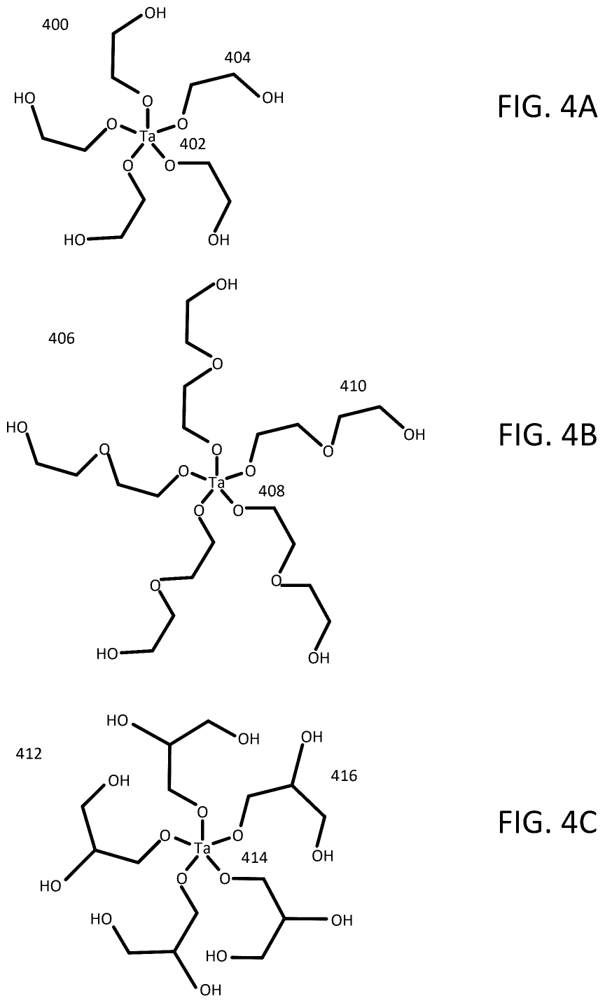

FIGS. 4A, 4B, and 4C show exemplary organotantalum SOCFs. A person of ordinary skill in the art will understand that chemical structures may be different under various conditions, for example to achieve a more thermodynamically favorable conformation. However, the exemplary line formulas disclosed herein describe to a person of ordinary skill in the art the structure of certain exemplary SOCFs. FIG. 4A shows a line formula of tantalum ethylglycolate 400 (TEG), which includes a central tantalum atom 402 and five ethyl glycolate ligands 404. FIG. 4B shows a line formula of tantalum diethylglycolate 406 (TDEG), which includes a central tantalum atom 408 and five diethylglycolate ligands 410. FIG. 1C is a line formula of tantalum glycerolate 412 (TGLY), which includes a central tantalum atom 414 and five diethylglycolate ligands 416. These exemplary SOCFs cure into air-stable coatings that pyrolyze into crystalline TaC films. These three compounds may be synthesized through a reaction using non-toxic, commercially-available reagents.

The ligands 404 and 410 in exemplary complexes TEG 400 and TDEG 406 are glycolates, which are built from the ethyleneoxy (—CH₂CH₂O—) structural unit. This moiety is a molecular building block that uses the electronegative oxygen atom to generate intermolecular and intramolecular non-covalent interactions in supramolecular and organometallic compounds. The ligands 404 and 410 of TEG 400 and TDEG 406 are the conjugate bases for ethylene glycol and diethylene glycol, respectively. These glycolate ligands 404 and 410 demonstrate a high degree of conformational freedom, which keeps TEG 400 and TDEG 406 in a liquid state at 25° C. Previous literature has also shown that glycolates can coordinate as polydentate or as bridging ligands to tantalum centers. See, e.g., (1) Bo, C.; Fandos, R.; Feliz, M.; Hernández, C.; Otero, A.; Rodríguez, A.; Ruiz, M. J.; Pastor, C. Fac versus Mer Coordination for a Tridentate Diethylene Glyclolate Ligand in Tantalum Complexes: A Combined Experimental and Theoretical Study. Organometallics 2006, 25 (14), 3336-3344. DOI:10.1021/om060254e; (2) Mehrotra, R. C.; Kapoor, P. N. Organic Compounds of Tantalum. Journal of the Less Common Metals 1966, 10 (4), 237-245. DOI:10.1016/0022-5088(66)90024-5; (3) Mehrotra, R. C.; Rai, A. K.; Kapoor, P. N.; Bohra, R. Organic Derivatives of Niobium(v) and Tantalum(v). Inorganica Chimica Acta 1976, 16, 237-267. DOI:10.1016/s0020-1693(00)91720-1.

The terminal —OH (hydroxyl) functionalities on glycolate ligands 404 and 410 form strongly coordinating intermolecular hydrogen bonds, —OH to —OH and —OH to —CH2—O—CH2—. Glycolate ligands 404 and 410 are chemically stable linear chains and do not readily degrade. Derived from ethylene glycol and diethylene glycol, ligands 404 and 410 have low toxicity, and by coordinating to a non-toxic tantalum center (402 and 408, respectively), the complexes TEG 400 and TDEG 406 also have low toxicity.

The ligands 416 in TGLY 412 are glycerolates, the conjugate base of glycerol, a simple liquid triol with a propane backbone. Like the glycolate ligands 404 and 410, this moiety has enough degrees of freedom to keep TGLY 412 a liquid at 25° C. The ligands 416 also participate in strong non-covalent intermolecular and intramolecular interactions through the oxygen atom in the hydroxyl groups. Past studies have shown that glycerolate ligands use these oxygens to form metal complexes as a polydentate or a bridging ligand. Terminal hydroxyl functionalities on the glycerolate ligands 416 form strongly coordinating intermolecular —OH to —OH hydrogen bonds. The glycerolate ligands 416 are also chemically stable linear chains and do not degrade easily. Glycerol possesses low toxicity, and when the ligand is coordinated to non-toxic tantalum 414, the complex 412 also exhibits low toxicity.

For simplicity, these three exemplary complexes (TEG 100, TDEG 106, and TGLY 412) are depicted as five ligands surrounding the metal center. In practice the ligands in the liquid bulk are flexible and conformationally labile, dynamically changing between the monodentate, polydentate, and bridging coordination states.

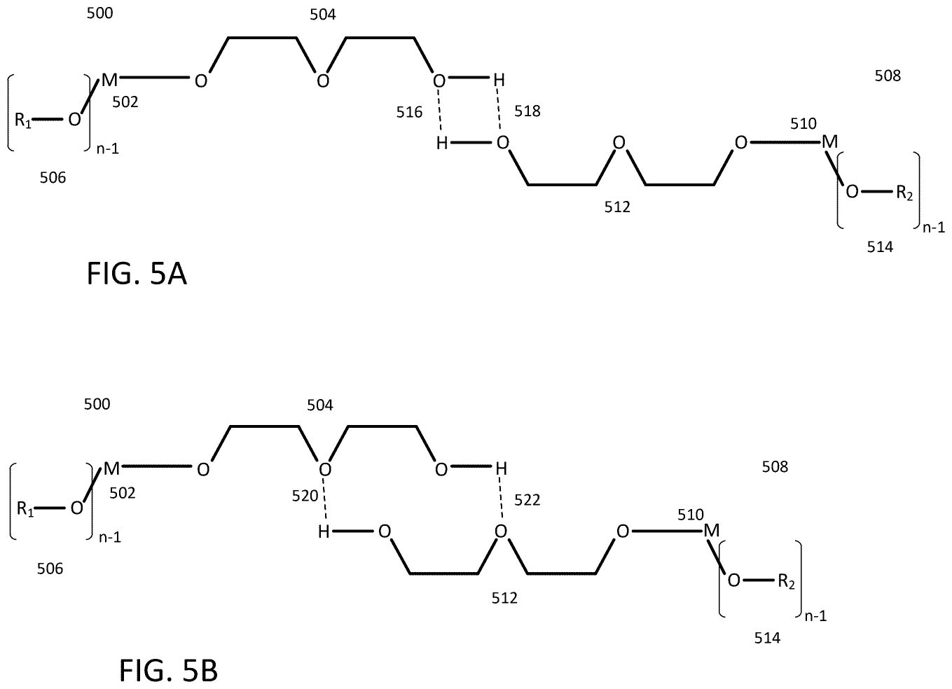

As shown in FIGS. 5A and 5B, molecules in exemplary SOCFs may be coupled to neighboring molecules through a dynamic and complex network of hydrogen bonding through functional groups on the ligands. FIGS. 5A and 5B show two exemplary SOCFs, 500 and 508, each having a central metal atom (502 and 510, respectively), a diethylglycolate ligand (504 and 512, respectively), and additional ligands (506 and 514, respectively). FIG. 5A shows one example of the interaction of SOCFs 500 and 508 through hydrogen bonds 516 and 518. FIG. 5B shows another example of interactions of SOCFs 500 and 508 through hydrogen bonds 520 and 522.

As shown in FIGS. 6A, 6B, 6C, and 6D, molecules in exemplary SOCFs may be coupled to neighboring molecules through monodentate, polydentate, and bridging coordination states. FIG. 6A shows an exemplary SOCF 600 having a central metal atom 602, a diethylglycolate ligand 604, and additional ligands 606. SOCF 600 is coordinated via bridging 614 to the central metal atom 610 of another exemplary SOCF, 608, which also has additional ligands 612. FIG. 6B shows an exemplary SOCF 616 having a central metal atom 618, a diethylglycolate ligand 620, and additional ligands 622. SOCF 616 is coordinated via bridging 630 to the central metal atom 626 of another exemplary SOCF 624, which also has additional ligands 628. FIG. 6C shows an exemplary SOCF 632 having a diethylglycolate ligand 634 in a polydentate (i.e., in this example, bidentate) state, wherein the ligand 634 is coupled to the central metal atom 636 via two atoms. FIG. 6D shows an exemplary SOCF 640 having two diethylglycolate ligands 642 and 644 in a polydentate (i.e., tridentate) state, wherein the ligands 642 and 644 are coupled to the central metal atom 646 via three atoms.

It is well established in literature, that an interconnected supramolecular framework which has reversible non-covalent interactions in thermodynamic equilibrium generates cooperative behavior leading to a self-organizing system. See, e.g., (1) Abe, Y.; Kimata, Y.; Gunji, T.; Nagao, Y.; Misono, T. Preparation of Polymetalloxanes as a Precursor for Oxide Fibers from Metal Chelate Complex. Journal of the Ceramic Society of Japan 1989, 97 (1125), 596-597. DOI:10.2109/jcersj.97.596; and (2) Wang, C.; Zhou, H.; Wen, S.; Chen, Z.; Du, Y.; Shi, L.; Li, B. Metallocene-Based Covalent Metal-Organic Porous Polymers and Their Derivatives. Materials Design 2023, 225, 111547. DOI:10.1016/j.matdes.2022.111547.

It is understood that this molecular self-organization in SOCFs produces a thermodynamically favorable energy state locally which stabilizes coatings formed from these SOCFs against hydrolysis. It is more favorable energetically for the metal centers in these complexes to coordinate to a ligand rather than have it displaced by water during hydrolysis. To explain the polymerization the SOCFs undergo to form a solvent-resistant and moisture-resistant film, it is understood that water in the air catalyzes the formation of bridging ligands that have enough conformational freedom to allow the metal centers to adopt energetically favorable geometries stabilized by Ta—O ligand coordination, making hydrolysis thermodynamically unfavorable. The metal centers may be further stabilized by hydrogen bonding occurring within the film.

The synthesis of SOCFs in accordance with the present disclosure may in some embodiments be done via ligand substitution. In some embodiments, this synthesis may be done without solvent, without purification, and such that the reaction goes to completion at 25° C. According to some embodiments, the starting organometallic reagent has alkoxide ligands where the conjugate base of the ligand is a volatile liquid alcohol. According to some embodiments, this starting organometallic reagent is a liquid at 25° C. And according to some embodiments, the ligand-generating reagent, which produces the incoming ligand, is also a liquid at 25° C.

The starting organometallic reagent in this reaction may be a simple metal alkoxide, a class of compounds whose chemistry is well established. Used in the manufacturing of electronics, optics, and catalysts, there are a wide variety of metals that are commercially available as a metal alkoxide in high purity and large scale.

For SOCF synthesis, a starting organometallic reagent with sufficiently large alkoxide ligands will be a liquid at 25° C. and can be used. Ethoxide (—OCH2CH3), propoxide (—OCH2CH2CH3), or butoxide (—OCH2CH2CH2CH3) ligands are exemplary choices for coordinating to a large variety of metals. For example, zirconium (IV) ethoxide is a solid at 25° C., but the extra methylene group in the ligand for zirconium (IV) propoxide lowers the melting point producing a liquid. The exemplary SOCF complexes TEG, TDEG, and TGLY may use titanium ethoxide (TEO) as an starting organometallic reagent. For a large atom like tantalum, ethoxide has enough conformational freedom to produce a liquid at 25° C. The structure of the ligand-generating reagents for exemplary SOCFs TEG, TDEG, and TGLY are also liquids at 25° C. These ligand-generating reagents may be ethylene glycol, diethylene glycol, and glycerol, respectively.

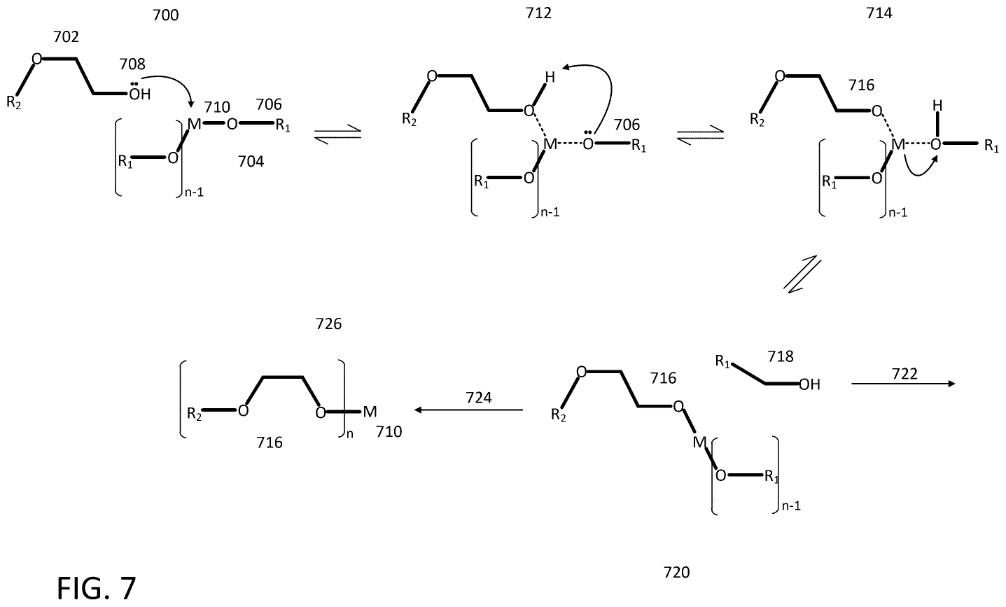

FIG. 7 shows the synthetic reaction of an exemplary SOCF 726 having a central metal atom 710 and an n-number of glycolate ligands 716, where R₂ represents additional ligand functional groups including —H or other alkyl groups. As shown in FIG. 7, in a first step 700 an ethylene-based glycol 702 mixed with an organometallic alkoxide 704, having an n-number of —O—R₁ ligands 706, which have a conjugate base that is a volatile alcohol, where R₁ represents additional ligand functional groups including —H or other alkyl groups. The terminal hydroxide group 708 of the ethylene-based glycol 702 coordinates to the central metal atom 710 of organometallic alkoxide 704. In a second and third step, 712 and 714 the alkoxide ligand 706 is displaced by glycolate ligand 716 from the ethylene-based glycol 702. Volatile alcohol 718 is produced from the displaced alkoxide ligand. In a fourth step 720, the volatile alcohol 718 is removed from the reaction under vacuum (722). As shown in FIG. 7, these steps 700, 712, 714, and 720 are in equilibrium. By permanently removing (722) the volatile alcohol 718, the chemical equilibrium will shift toward generating more products having ethylene-based glycolate ligand 716, per Le Chatelier's principle. At step 724, the ligand substitution of the prior steps are repeated n−1 times, and as a result substantially all of the organometallic alkoxide 704 has been substituted with glycolate ligands 716, resulting in glycolate SOCF 726, having a central metal atom 710 and n-number of glycolate ligands 716.

For simplicity in describing the synthesis, FIG. 7 is shown for ethylene-based glycol 702 having ligands with R₂ functional groups and an organometallic alkoxide 704 having n-number of ligands having R₁ functional groups. However, it is understood that this synthesis could be performed using mixtures of reagents. For example, a mixture of two or more ligand-generating reagents could be used having different functional groups in place of R₂ shown in FIG. 7. Moreover, other ligand generating reagents could be used that are not ethylene-based glycols. Also for example, the starting organometallic alkoxide could have up to n-number of different ligands in place of the —O—R₁ ligands 706. In addition, the starting organometallic alkoxide 704 could be a mixture of organometallic alkoxides having different central metal atoms 710.

In one example, this synthesis was performed to produce the exemplary SOCF TEG. To perform this synthesis, 1 mol TEO and 5 mol of the ligand-generating group ethylene glycol were mixed in a glass vessel under ambient conditions. Upon mixing, the TEO and ligand-generating reagent liquid were not miscible, resulting in a cloudy emulsion. Immediately the reaction vessel became warm, indicating a favorable exothermic reaction as ethyleneglycolate ligands from the ligand-generating reagent displaced ethoxide coordinated to the tantalum metal center in TEO. After several seconds, the cloudy emulsion began to clear, and after 2 minutes only a clear liquid remained in the reaction vessel. The exothermicity of the ligand substitution signified an energetically favorable reaction. The newly formed clear liquid, however, was not the intended product (i.e., TEG). Because the ethoxide (TEO) and glycolate (TEG) ligands are labile, the liquid was a complex equilibrium where some tantalum centers were coordinated to the new ligands (glycolate) and others were still complexed to ethoxide. This ligand displacement reaction was carried out under vacuum. The side product of the ligand substitution of TEO was the conjugate base of the displaced ethoxide ligand, the volatile alcohol ethanol. Under reduced pressure, ethanol was permanently removed from the reaction mixture. Because reactants and products in chemical reactions are in equilibrium, by permanently removing the side product, the chemical equilibrium shifted toward generating more products (Le Chatelier's principle). After 24 hours under vacuum, the ethanol side product had been completely removed from the reaction mixture, and as a result the reactant TEO had been consumed, leaving substantially only TEG.

The SOCF according to the present disclosure may be cured into polymer films that exhibit chemical stability to air, water, and organic solvents. Such polymer films may be used to create coatings on any surface within a reactor or within any component within a reactor. For example, embodiments of the present disclosure may be used to create a coating on one or more surfaces of a crucible, an interior wall of a reactor, insulation, source retention elements, baffles, or any other structure shown or described herein. Such polymer films may allow articles made from graphite and other materials to be coated with metal carbides. Such articles may include an article designed for use in manufacturing wafers or boules for use in the manufacture of semiconductor chips. For example, the article may be a crucible, vessel, container, or part thereof, including a seed holder, lid, spacer ring, rod, liner, washer, shaft or porous barrier. In some embodiments, the crucible, vessel, container, or part thereof may be designed for use in the manufacture of silicon carbide wafers or boules. Polymer films or coatings according to the present disclosure can be continuous, discontinuous, or patterned. Such films or coatings can be single coatings or part of a multi-coating layer. Polymer films or coatings according to the present disclosure may be applied to one or more elements within a crystal growth system, either in their entirety or having portions coated, either as a single coating or multiple coatings or a patterned coating, for example, to achieve desired sublimation if such elements act as a secondary source or to reduce sublimation if such elements are not intended to serve as a secondary source. Polymer films or coatings according to the present disclosure may be applied to one or more elements within a crystal growth system as a controlled secondary source of SiC or carbon and/or to control the ratio of carbon and silicon in the vapor. Polymer films or coatings according to the present disclosure may act as a catalytic surface to help reduce contaminants.

Unlike metal alkoxides that decompose through hydrolysis when processed in air metal centers in SOCFs are more resistant to hydrolysis. The organometallic molecules form a complex network of coordination bonds with neighboring ligands creating a three-dimensional polymer network. Resistance to hydrolysis in the polymeric network is further enhanced by the thermodynamic stabilization of the noncovalent polydentate (chelate effect) and supramolecular (intermolecular hydrogen bonding) interactions. The lability of the flexible SOCF ligands allows the metal centers in the coatings to arrange, during air curing, into a thermodynamically favorable conformation (M-ligand-M) that is energetically more stable than the oxo bridges (M—O—M) produced through hydrolysis.

The flexible SOCF ligands and, the preferably liquid state of the raw materials, also can allow SOCFs to cure as continuous conformal films. These SOCF materials can coat a broad range of substrate morphologies (e.g., porous, fibrous, angular, curved, or flat) and length-scales (macro, micro, and nano).

The binding constant for the glycolate and glycerolate ligands to tantalum is so large that SOCFs can be dissolved in organic solvents, and the complexed metal centers will not disassociate from the ligands. This attribute allows SOCFs to be diluted into a solution for simple application by spray or dip coating without altering the chemical structure of the cured polymer films. A solution-based application such as dip coating has the additional benefit of penetrating into the porous morphology of a graphite substrate. For example, applying certain SOCFs on graphite or felt carbon articles that are coated through dip-coating allow pyrolyzed TEG SOCF polymer films to be deposited into the interior of the substrates through dip-coating.

Another advantage of certain SOCF films is the relatively low pyrolysis temperature (e.g., 1500° C.) needed to form crystalline TaC coatings. The combination of low pyrolysis temperature and chemical stability in SOCF films allow for continuous batch processing in a large-scale manufacturing environment.

Certain SOCF materials in accordance with the present disclosure may be coated on a host material that will be removed through sublimation, evaporation, or a chemical process, leaving the metal carbide structure as a self supported element. Such a self-supported element may be part of a PVT/CVT or CVD system. Parts made from such processes may be more porous than a solid metal.

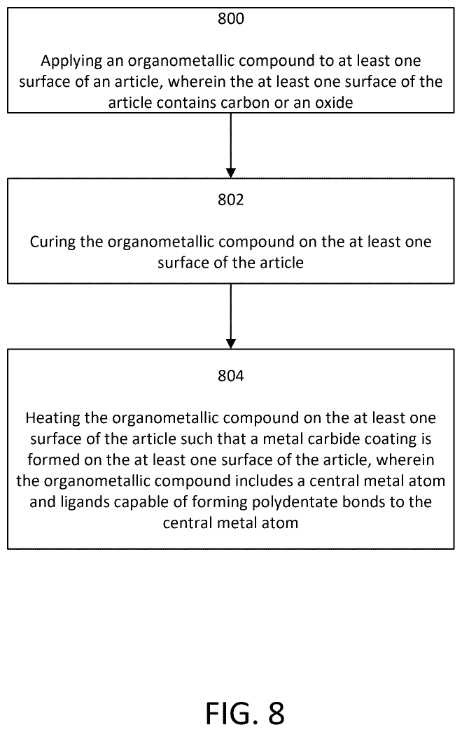

As shown in FIG. 8, certain aspects of this disclosure and their embodiments describe a method of creating an article for use in a crystal growth system, such method including: applying an organometallic compound to at least sone surface of an article, wherein the at least one surface of the article contains carbon or an oxide 800, curing the organometallic compound on the at least one surface of the article 802, and heating the organometallic compound on the at least one surface of the article such that a metal carbide coating is formed on the at least one surface of the article, wherein the organometallic compound includes a central metal atom and ligands capable of forming polydentate bonds to the central metal atom 804.

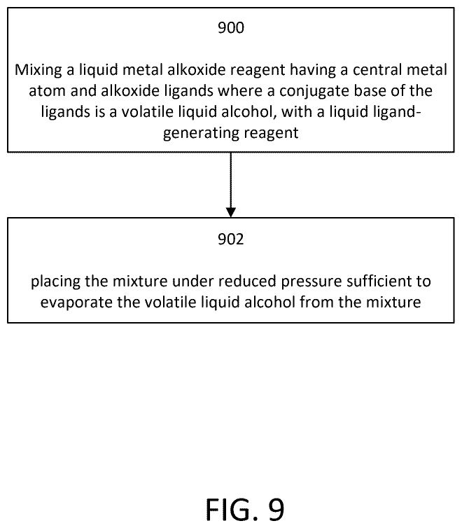

As shown in FIG. 9, certain aspects of this disclosure and their embodiments describe a method of synthesizing an organometallic compound, such method including: mixing a liquid metal alkoxide reagent having a central metal atom and alkoxide ligands where a conjugate base of the ligands is a volatile liquid alcohol, with a liquid ligand-generating reagent 900, and placing the mixture under reduced pressure sufficient to evaporate the volatile liquid alcohol from the mixture 902.

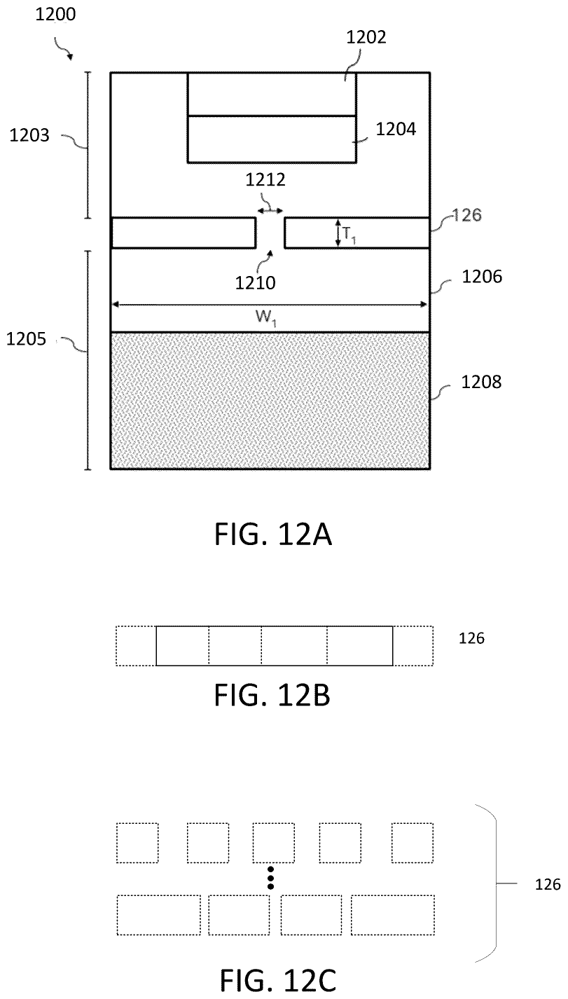

In any of the simplified crystal growth systems with a baffle 126 depicted in FIGS. 12A-18 the baffle 126 may provide vapor transport of a silicon carbide source vapor through a first portion of the baffle 126 at a first rate. In some embodiments, the silicon carbide vapor may be transported through a second portion of the baffle 126 (e.g., including one or more apertures), at a second rate. The first rate may be different than the second rate. For example, the baffle 126 may provide an avenue for source vapor to diffuse through the material of the baffle 126 at a first rate, while source vapor is transported through an aperture unimpeded by the material of the baffle 126 at a second rate. In some embodiments, the baffle 126 may be spaced apart from the seed holder 1202 and is not coupled to the seed holder 1202. In some embodiments, the baffle 126 may impede or otherwise alter heat transfer or thermal energy within the crystal growth chamber in a crystal growth process.

In some embodiments, the baffle 126 may be, at least partially, made of graphite. In some embodiments, the baffle 126 made at least partially of graphite may include a coating on at least a portion of the graphite. In some embodiments, the coating on the baffle 126 made of graphite may be a pyrolytic coating. In some embodiments, the coating on the baffle 126 made of graphite may be tantalum carbide. In some embodiments, the coating on the baffle 126 may hinder particulate matter larger than the source vapor from reaching a seed crystal 1204. The seed crystal 1204 may be a silicon carbide seed crystal. In some embodiments, the baffle 126 may be porous graphite. Porous graphite may provide a less hindered pathway for source vapor to diffuse through.

In some embodiments, the baffle 126 may be spaced apart from a seed holder 1202 and is not coupled to the seed holder 1202. In some embodiments, the baffle 126 may be spaced apart from a source material 1208 and is not coupled to the source material 1208. The source material 1208 may be a silicon carbide vapor source material. In some embodiments, the baffle may be coupled to a side wall of a crucible 1206.

FIG. 12A depicts a simplified view of a crystal growth system 1200 according to example aspects of the present disclosure. The crystal growth system 1200 includes the seed holder 1202 configured to hold the seed crystal 1204. The seed crystal 1204 may provide a growth surface for growth of the silicon carbide crystalline material in a crystal growth process. The crystal growth system 1200 includes the crucible 1206 defining a crystal growth chamber. The crystal growth system 1200 includes the source material 1208. The crystal growth system 1200 includes the baffle 126 within the crystal growth chamber that is spaced apart from the source material 1208. In some embodiments, the baffle 126 may extend between the inner walls of the crucible 1206, such that the crucible 1206 is bisected or divided into an upper portion 1203 and a lower portion 1205 by the baffle 126. The upper portion 1203 and the lower portion 1205 may have the same or different volumes. In some examples, the baffle 126 may be coupled to a side wall of the crucible 1206. In some examples, the baffle 126 may not fully extend between the inner walls of the crucible 1206.

The baffle 126 has a long dimension (e.g., width) W1 and a thickness T1. The thickness T1 is in a general direction of vapor transport through the baffle 126. In some embodiments, the long dimension W1 is in a direction that is non-perpendicular to the growth surface of the seed crystal 1204.

FIG. 12B depicts a simplified view of baffle 126 according to some aspects of the present disclosure. As shown in FIG. 12B, baffle 126 may include apertures, and may extend to the side walls of the crucible, or may not extend to the sidewalls of the crucible.

FIG. 12C depicts a simplified view of baffle 126 according to some aspects of the present disclosure. As shown in FIG. 12C, baffle 126 may include multiple baffle structures, which may be spaced apart from one another or may be in contact with one another.

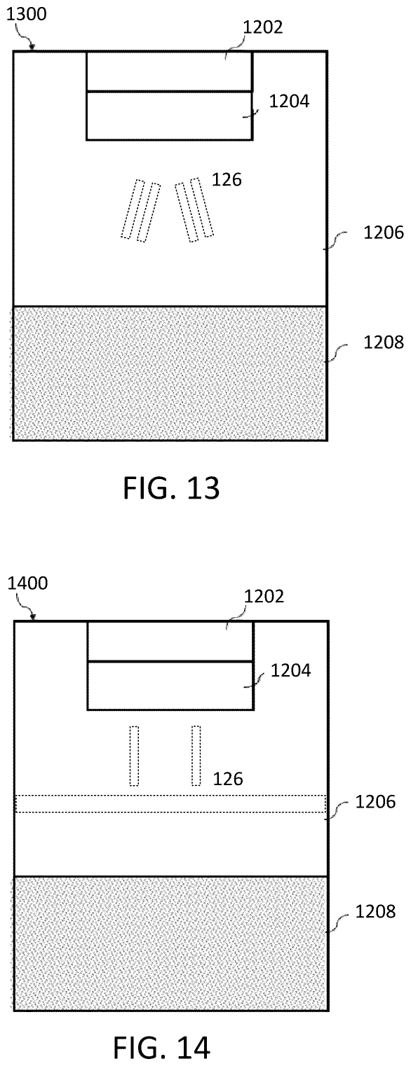

FIGS. 13, 14, 15, 16, 17, and 18 depict simplified views of baffle 126 according to some aspects of the present disclosure in the context of crystal growth systems 1300, 1400, 1500, 1600, 1700, and 1800. As shown in FIG. 13, in some embodiments of the present disclosure, baffle 126 may include one or more baffle plates, in any orientation relative to the seed holder 1202 or the source material 1208. As shown in FIG. 14, in some embodiments of the present disclosure, baffle 126 may include two or more baffle structures, whether of the same type or of differing types, and such baffle structures may be of differing orientations relative to each other.

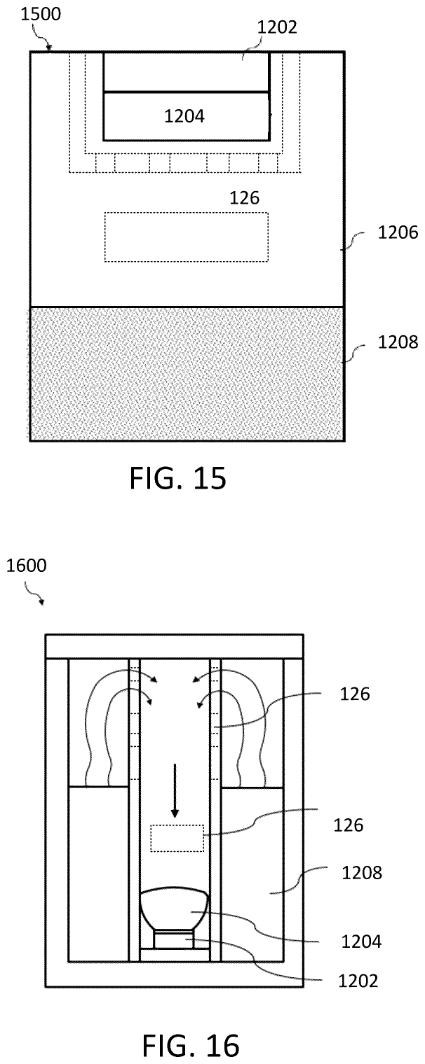

As shown in FIG. 15, in some embodiments of the present disclosure the crystal growth system 1500 includes a baffle, the seed holder 1202, the seed crystal 1204, the crucible 1206, and the source material 1208. An element of the baffle 126 may be positioned such that the baffle 126 extends around at least three sides of the seed crystal 1204, with the longest dimension located below the seed crystal 1204. The baffle 126 may be referred to as a shell structure as it provides a shell around the seed crystal 1204. The baffle 126 may be graphite, such as porous graphite. The baffle 126 may include one or more apertures that assist in the transport of source vapor from the source material 1208 to the seed crystal 1204, or may not include any apertures. Baffle 126 may also include additional elements, such as any of the exemplary baffles contemplated by the present disclosure, such as any of the baffles depicted in FIGS. 1-3 or 12A-14, and such additional elements may be situated between the source material 1208 and the seed crystal 1204.

As shown in FIG. 16, example crystal growth system 1600 includes a baffle 126, a seed holder 1202, a seed crystal 1204, a crucible 1206, and the source material 1208. The baffle 126 may include a tubular baffle structure. The seed crystal 1204 may be within the tubular baffle 126. The baffle 126 may be graphite, such as porous graphite. The baffle 126 may include one or more apertures that assist in the transport of source vapor from the source material 1208 to the seed crystal 1204, or may not include any apertures. Baffle 126 may also include additional elements, such as any of the exemplary baffles contemplated by the present disclosure, such as any of the baffles depicted in FIGS. 1-3 or 12A-14, and such additional elements may be situated between the source material 1208 and the seed crystal 1204.

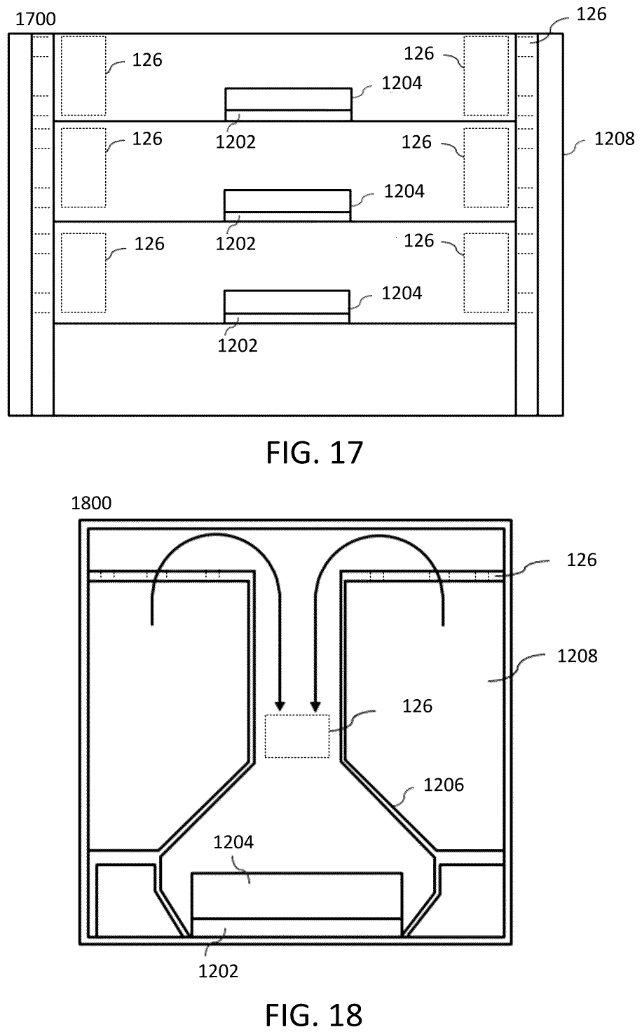

As shown in FIG. 17 example crystal growth systems 1700 may be used to grow a plurality of silicon carbide boules according to example embodiments of the present disclosure. In FIG. 17, the crystal growth system 1700 includes a plurality of seed holders 1202 and seed crystals 1204 arranged in different crystal growth chambers. A baffle 126 may separate the seed crystals 1204 from a source material 1208. As depicted in FIG. 17, the baffle 126 may include one or more apertures to assist with vapor transport from the source material 1208 to the seed crystals 1204. The apertures may have a shape and/or arrangement as any of the apertures provided herein. In some embodiments, as depicted in FIG. 17, the crystal growth system 1700 may include one or more additional baffles elements in each chamber. The additional baffle elements 126 may be arranged between the source material 1208 and the seed crystal 1204 in each chamber. Each of the one or more additional baffles elements 126 may include any of the baffles contemplated by the present disclosure, such as any of the baffles depicted in FIGS. 1-3 or 12A-14.

FIG. 18 depicts example crystal growth systems 1800 according to example embodiments of the present disclosure. In FIG. 18, the crystal growth system 1800 includes a seed holder 1202 and a seed crystal 1204 arranged within a crucible 1206. The crucible 1206 may have one or more angled sidewalls. The crystal growth system 1800 includes a source material 1208. The baffle 126 may be on top of the source material 1208 and may separate the source material 1208 from the reaction chamber defined by the crucible 1206. As depicted in FIG. 18, the baffle 126 may include one or more apertures to assist with vapor transport from the source material 1208 to the seed crystal 1204. The apertures may have a shape and/or arrangement as any of the apertures provided herein. The system 1800 may further include additional baffle elements 126. The second baffle may be in the transport path between the source material 1208 and the seed crystal 1204. The second baffle 126 may include any of the baffles contemplated by the present disclosure, such as any of the baffles depicted in FIGS. 1-3 or 12A-14.

In any crystal growth system incorporating aspects of the present disclosure, including exemplary crystal growth systems shown in FIGS. 1-3 and 12A-18, a baffle system may include single or multiple elements that may effect, alter, or provide a temperature gradient in a desired manner relative to the crystal growth surface. Such exemplary baffle systems may also effect, alter, or provide a vapor pressure gradient, vapor flux, or vapor flow. Such vapor pressure gradient, vapor flus, or vapor flow may be between any of the following: a SiC source, multiple SiC sources, one or more secondary Si or SiC sources, or one or more dopant sources. Such vapor pressure gradient, vapor flus, or vapor flow may be relative to the crystal growth surface, a side surface of the crystal, areas within the crystal growth system susceptible to parasitic growth, filtering structures, or other inclusions from the crystal. In some embodiments, different elements of the baffle system may provide different features. For example, a baffle system may include one or more elements that perform one or more of the following functions, which may be present in any combination: filtering; acting as a secondary source, for example a graphite element that provides a graphite source; effecting, altering, or providing a temperature gradient; effecting altering, or providing a vapor pressure gradient. In some embodiments, a baffle system may include one or more elements with apertures, pores, voids, cavities, indentations, and/or protrusions. In some embodiments, a baffle system may include one or more elements that may be coated in whole or in part with a carbide coating, including TaC. A baffle system may include one or more elements coated, or having portions coated, with a coating, or multiple coatings, or a patterned coating, for example, to achieve desired sublimation if acting as a secondary source or to reduce sublimation if not intended to serve as a secondary source. Individual baffles or elements in a baffle system can serve duplicate or different functions.

Graphite structures may be treated to reduce particle emission, as disclosed in U.S. Provisional Application Ser. No. 63/700,630, filed on Sep. 28, 2024, which is hereby incorporated by reference.

Further definitions and embodiments are discussed below.

In the above-description of various embodiments of present inventive concepts, it is to be understood that the terminology used herein is for the purpose of describing particular embodiments only and is not intended to be limiting of present inventive concepts. Unless otherwise defined, all terms (including technical and scientific terms) used herein have the same meaning as commonly understood by one of ordinary skill in the art to which present inventive concepts belong. It will be further understood that terms, such as those defined in commonly used dictionaries, should be interpreted as having a meaning that is consistent with their meaning in the context of this specification and the relevant art and will not be interpreted in an idealized or overly formal sense unless expressly so defined herein.

As used herein, the singular forms “a”, “an” and “the” are intended to include the plural forms as well, unless the context clearly indicates otherwise. Well-known functions or constructions may not be described in detail for brevity and/or clarity. The term “and/or” (abbreviated “/”) includes any and all combinations of one or more of the associated listed items.

As used herein, the terms “comprise”, “comprising”, “comprises”, “include”, “including”, “includes”, “have”, “has”, “having”, or variants thereof are open-ended, and include one or more stated features, integers, elements, steps, components or functions but does not preclude the presence or addition of one or more other features, integers, elements, steps, components, functions or groups thereof. Furthermore, as used herein, the common abbreviation “e.g.”, which derives from the Latin phrase “exempli gratia,” may be used to introduce or specify a general example or examples of a previously mentioned item, and is not intended to be limiting of such item. The common abbreviation “i.e.”, which derives from the Latin phrase “id est,” may be used to specify a particular item from a more general recitation.

As used herein, “metal” may also include metalloids, including silicon, germanium, arsenic, antimony, tellurium, or polonium.

As used herein, the terms adhesive, bond, and coating are used interchangeably.

Example embodiments are described herein. Many variations and modifications can be made to the embodiments without substantially departing from the principles of the present inventive concepts. All such variations and modifications are intended to be included herein within the scope of present inventive concepts. Accordingly, the above disclosed subject matter is to be considered illustrative, and not restrictive, and the examples of embodiments are intended to cover all such modifications, enhancements, and other embodiments, which fall within the spirit and scope of present inventive concepts. Thus, to the maximum extent allowed by law, the scope of present inventive concepts are to be determined by the broadest permissible interpretation of the present disclosure including the examples of embodiments and their equivalents, and shall not be restricted or limited by the foregoing detailed description.

What is claimed is:

1. A method for creating an article for use in a crystal growth system, comprising:
applying an organometallic compound to at least one surface of an article, wherein the at least one surface of the article contains carbon or an oxide;
curing the organometallic compound on the at least one surface of the article; and
heating the organometallic compound on the at least one surface of the article such that the metal carbide coating is formed on the at least one surface of the article;
wherein the organometallic compound consists of:
a central metal atom; and
ligands capable of forming polydentate bonds to the central metal atom.

2. The method of claim 1, wherein the article for use in a crystal growth system is one of a seed holder, crucible, lid, spacer ring, rod, liner, washer, shaft, porous barrier, or filter.

3. The method of claim 2, wherein the crystal growth system is a silicon carbide crystal growth sublimation system.

4. The method of claim 1, wherein the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof.

5. The method of claim 1, wherein the ligands capable of forming polydentate bonds to the central metal atom are polar.

6. The method of claim 1, wherein the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

7. The method of claim 1, wherein the article is made from a material is selected from the group consisting of graphite, hard carbon, carbon fiber, felt carbon, vitreous carbon, pyrolytic carbon, silicon carbide, tungsten carbide, quartz, glass, ferric oxides, magnesium oxides, aluminum oxides, titanium oxides, cerium oxide, niobium oxide, and zinc oxide.

8. The method of claim 7, wherein the at least one surface of the article is porous.

9. The method of claim 7, wherein the at least one surface of the article is nonporous.

10. The method of claim 7, wherein the organometallic compound on the at least one surface of the article is cured at about 25° C. and at ambient pressure.

11. The method of claim 1, wherein the organometallic compound on the at least one surface of the article is heated at 2000° C. or less.

12. The method of claim 1, wherein the organometallic compound on the at least one surface of the article is heated at 1700° C. or less.

13. The method of claim 1, wherein the organometallic compound on the at least one surface of the article is heated at 1500° C. or less.

14. The method of claim 1, wherein the organometallic compound on the at least one surface of the article is heated for 24 hours or less.

15. The method of claim 1, wherein the metal carbide coating is formed on the at least one surface of the article has a thickness greater than 35 μm.

16. The method of claim 6, wherein the central metal atom and ligands of the organometallic compound are selected such that the organometallic compound is a liquid at 25° C. and 1 atm.

17. The method of claim 6, wherein the alkyl group of the alkyl amines, alkyl acetates, alkyl alcohols, alkyl glycols, alkyl diols, alkyl nitrites, alkyl halides, alkyl aromatics, or alkylated charge transfer donor-acceptor pairs is an ethyl, propyl, butyl group, or a mixture thereof.

18. The method of claim 17, wherein all of the ligands are the same.

19. The method of claim 17, wherein the ligands are selected from the group of glycolate, diethylene glycolate, glycerolate, or a mixture thereof.

20. The method of claim 17, wherein the central metal atom is tantalum.

21. The method of claim 17, wherein the organometallic compound is tantalum ethylglycolate.

22. The method of claim 17, wherein the organometallic compound is tantalum diethylglycolate.

23. The method of claim 17, wherein the organometallic compound is tantalum glycerolate.

24. The method of claim 1, wherein the organometallic compound is applied to the at least one surface of the article via at least one of a spray application, dip application, electrostatic application.

25. The method of claim 1, wherein the organometallic compound is applied to the at least one surface of the article in a solvent.

26. The method of claim 1, wherein the crystal growth system uses a chemical vapor deposition process.

27. The method of claim 1, wherein the crystal growth system uses a physical vapor transport process.

28. The method of claim 1, wherein the crystal growth system uses a hybrid of a chemical vapor deposition process and a physical vapor transport process.

29. An organometallic compound which comprises:
a central metal atom; and
organic ligands capable of forming polydentate bonds to the central metal atom.

30. The organometallic compound of claim 29, wherein the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof.

31. The organometallic compound of claim 29, wherein the ligands capable of forming polydentate bonds to the central metal atom are polar.

32. The organometallic compound of claim 29, wherein the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

33. The organometallic compound of claim 32, wherein the alkyl groups of the alkyl amines, alkyl acetates, alkyl alcohols, alkyl glycols, alkyl diols, alkyl nitrites, alkyl halides, alkyl aromatics, or alkylated charge transfer donor-acceptor pairs is an ethyl, propyl, butyl group, or a mixture thereof.

34. The organometallic compound of claim 29, wherein the central metal atom and ligands are selected such that the organometallic compound is a liquid at 25° C. and 1 atm.

35. The organometallic compound of claim 29, wherein the ligands are selected from the group of glycolate, diethylene glycolate, glycerolate, or a mixture thereof.

36. The organometallic compound of claim 29, wherein all of the ligands are the same.

37. The organometallic compound of claim 29, wherein the central metal atom is tantalum.

38. The organometallic compound of claim 29, wherein the organometallic compound is tantalum ethylglycolate.

39. The organometallic compound of claim 29, wherein the organometallic compound is tantalum diethylglycolate.

40. The organometallic compound of claim 29, wherein the organometallic compound is tantalum glycerolate.

41. An article having a metal carbide coating, comprising:
an organometallic compound applied to at least one surface of an article that contains carbon or an oxide, the applied organometallic compound having been cured and pyrolyzed to form a metal carbide coating on the at least one surface of the article
wherein the organometallic compound consists of:
a central metal atom; and
ligands capable of forming polydentate bonds to the central metal atom.

42. The article of claim 41, wherein the central metal atom is selected from the group consisting of chromium, hafnium, iridium, molybdenum, niobium, osmium, rhenium, rhodium, ruthenium, tantalum, titanium, tungsten, vanadium, zirconium, or a mixture thereof.

43. The article of claim 41, wherein the ligands capable of forming polydentate bonds to the central metal atom are polar.

44. The article of claim 41, wherein the ligands capable of forming polydentate bonds to the central metal atom are selected from the group consisting of alkyl amines, alkyl acetates, alkyl alcohols, alkyl glycols, alkyl diols, alkyl nitrites, alkyl halides, alkyl aromatics, alkylated charge transfer donor-acceptor pairs, or a mixture thereof.

45. The article of claim 41, wherein the article is made from a material selected from the group consisting of graphite, hard carbon, carbon fiber, felt carbon, vitreous carbon, pyrolytic carbon, silicon carbide, tungsten carbide, quartz, glass, ferric oxides, magnesium oxides, aluminum oxides, titanium oxides, cerium oxide, niobium oxide, and zinc oxide.

46. The article of claim 45, wherein the at least one surface of the article is porous.

47. The article of claim 45, wherein the at least one surface of the article is nonporous.

48. The article of claim 41, wherein the organometallic compound on the at least one surface of the article is cured at about 25° C. and at ambient pressure.

49. The article of claim 41, wherein the organometallic compound on the at least one surface of the article is pyrolyzed at 2000° C. or less.

50. The article of claim 41, wherein the organometallic compound on the at least one surface of the article is pyrolyzed at 1700° C. or less.

51. The article of claim 41, wherein the organometallic compound on the at least one surface of the article is pyrolyzed at 1500° C. or less.

52. The article of claim 41, wherein the organometallic compound on the at least one surface of the article is pyrolyzed for 24 hours or less.

53. The article of claim 41, wherein the metal carbide coating is formed on the at least one surface of the article has a thickness greater than 35 μm.

54. The article of claim 41, wherein the central metal atom and ligands of the organometallic compound are selected such that the organometallic compound is a liquid at 25° C. and 1 atm.

55. The article of claim 44, wherein the alkyl group of the alkyl amines, alkyl acetates, alkyl glycols, alkyl alcohols, alkyl diols, alkyl nitrites, alkyl halides, alkyl aromatics, or alkylated charge transfer donor-acceptor pairs, is an ethyl, propyl, butyl group, or a mixture thereof.

56. The article of claim 55, wherein all of the ligands are the same.

57. The article of claim 55, wherein the ligands are selected from the group of glycolate, diethylene glycolate, glycerolate, or a mixture thereof.

58. The article of claim 57, wherein the central metal atom is tantalum.
